(19) United States
(12) Patent Application Publication
(10) Pub. No.: US 2026/0221191 A1
(43) Pub. Date: Jul. 30, 2026

(54) NONVOLATILE MEMORY DEVICE AND ELECTRONIC SYSTEM INCLUDING THE SAME

(71) Applicant: SAMSUNG ELECTRONICS CO., LTD., Suwon-si (KR)

(72) Inventors: Kohji KANAMORI, Suwon-si (KR); Seunghyun LEE, Suwon-si (KR); Kyungdong KIM, Suwon-si (KR); Jeehoon HAN, Suwon-si (KR)

(73) Assignee: SAMSUNG ELECTRONICS CO., LTD., Suwon-si (KR)

(21) Appl. No.: 19/290,913

(22) Filed: Aug. 5, 2025

(30) Foreign Application Priority Data
Jan. 24, 2025 (KR) 10-2025-0011536

(51) Int. Cl. G11C 16/10; G11C 16/04; G11C 16/08; G11C 16/26

(52) U.S. Cl. CPC G11C 16/10; G11C 16/0483; G11C 16/08; G11C 16/26

(57) ABSTRACT

Disclosed is a memory device which includes a first memory cell structure including a plurality of first memory cells connected to a first word line and a plurality of first bit lines, and a second memory cell structure provided on the first memory cell structure and including a plurality of second memory cells connected to a second word line and a plurality of second bit lines. The first word line and the second word line are electrically connected, the plurality of first memory cells are configured to store first sub-page data, the plurality of second memory cells are configured to store second sub-page data, the first sub-page data and the second sub-page data are included in first page data, and the first page data is a minimum program unit of the memory device.

### CROSS-REFERENCE TO RELATED APPLICATIONS

This application claims priority under 35 U.S.C. § 119 to Korean Patent Application No. 10-2025-0011536 filed on January 24, 2025, in the Korean Intellectual Property Office, the disclosures of which are incorporated by reference herein in their entireties.

### BACKGROUND

Embodiments of the present disclosure described herein relate to a nonvolatile memory device and an electronic system including the same.

An electronic system which needs to store data may require a memory device capable of storing a large amount of data. To this end, a way to increase a data storage capacity of the memory device is being developed. For example, as one of methods for increasing the data storage capacity of the memory device, there is being developed a semiconductor device including memory cells arranged in a three-dimensional structure instead of memory cells arranged in a two-dimensional structure.

### SUMMARY

Embodiments of the present disclosure provide a nonvolatile memory device with improved performance and an electronic system including the same.

According to an embodiment, a memory device includes a first memory cell structure including a plurality of first memory cells connected to a first word line and a plurality of first bit lines, and a second memory cell structure provided on the first memory cell structure and including a plurality of second memory cells connected to a second word line and a plurality of second bit lines. The first word line and the second word line are electrically connected, the plurality of first memory cells are configured to store first sub-page data, the plurality of second memory cells are configured to store second sub-page data, the first sub-page data and the second sub-page data are included in first page data, and the first page data is a minimum program unit of the memory device.

According to an embodiment, a memory device includes a peripheral circuit structure including an address decoder and a page buffer, and a first memory cell structure to an n-th memory cell structure stacked on the peripheral circuit structure. The first memory cell structure to the n-th memory cell structure include a plurality of first memory cells to a plurality of n-th memory cells respectively connected to a first word line to an n-th word line. The first memory cells to the n-th memory cells are connected to a plurality of first bit lines to a plurality of n-th bit lines, respectively, the plurality of first memory cells to the plurality of n-th memory cells store first sub-page data to n-th sub-page data, respectively, the first sub-page data to the n-th sub-page data are included in first page data, the first word line to the n-th word line are electrically connected, and the first page data is a minimum program unit of the memory device.

According to an embodiment, an electronic system includes a memory device including a peripheral circuit structure and a memory block on the peripheral circuit structure, and a controller electrically connected to the memory device through an input/output pad, and configured to control the memory device. The memory block includes a first memory cell structure to an n-th memory cell structure stacked on the peripheral circuit structure, the first memory cell structure to the n-th memory cell structure include a plurality of first memory cells to a plurality of n-th memory cells respectively connected to a first word line to an n-th word line, and the first memory cells to the n-th memory cells are connected to a plurality of first bit lines to a plurality of n-th bit lines, respectively. The plurality of first memory cells to the plurality of n-th memory cells store first sub-page data to n-th sub-page data, respectively, the first sub-page data to the n-th sub-page data are included in first page data, the first word line to the n-th word line are electrically connected, and the first page data is a minimum program unit of the memory device.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a nonvolatile memory device according to an embodiment of the present disclosure.

FIG. 2 is a diagram for describing an example of a memory block of FIG. 1.

FIG. 3 is a circuit diagram schematically illustrating a nonvolatile memory device of FIG. 1.

FIG. 4 is a circuit diagram illustrating a memory block of FIG. 1.

FIG. 5A, FIG. 5B and FIG. 5C are diagrams for describing a page configuration of a memory cell array of FIG. 1.

FIG. 6A and FIG. 6B are diagrams for describing a page size of a nonvolatile memory device according to an embodiment of the present disclosure.

FIG. 7 is a diagram for describing a characteristic according to a page configuration of a nonvolatile memory device of FIG. 1.

FIG. 8 is a block diagram for describing a page buffer of FIG. 1.

FIG. 9A and FIG. 9B are diagrams for describing an example of a read operation and a program operation of a nonvolatile memory device of FIG. 1.

FIG. 10 is another example of a circuit diagram schematically illustrating a nonvolatile memory device of FIG. 1.

FIG. 11 is a cross-sectional view of a nonvolatile memory device according to an embodiment of the present disclosure.

FIG. 12 is a diagram schematically illustrating an electronic system including a semiconductor memory device according to an embodiment of the present disclosure.

### DETAILED DESCRIPTION

Below, embodiments of the present disclosure will be described in detail and clearly to such an extent that an ordinary one in the art easily carries out the present disclosure.

In the specification, function blocks of drawings, which respectively correspond to the terms “block”, “unit”, “logic”, etc., may be implemented in the form of software, hardware, or a combination thereof.

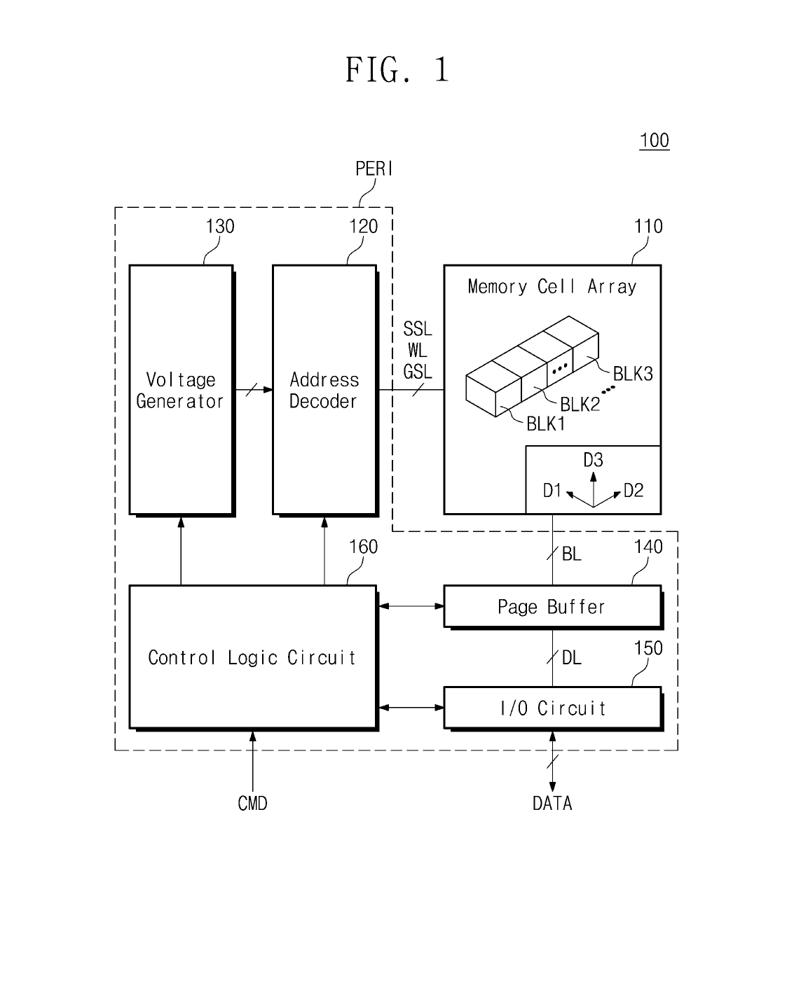

FIG. 1 is a block diagram illustrating a nonvolatile memory device according to an embodiment of the present disclosure. Referring to FIG. 1, a nonvolatile memory device 100 may include a memory cell array 110, an address decoder 120, a voltage generator 130, a page buffer 140, an input/output circuit 150, and a control logic circuit 160.

The memory cell array 110 includes a plurality of memory blocks BLK1 to BLKz. Each of the plurality of memory blocks BLK1 to BLKz may include a plurality of memory cells arranged in a three-dimensional structure. For example, each of the plurality of memory blocks BLK1 to BLKz may include structures stacked along a third direction D3 on a plane extending along first and second directions D1 and D2 crossing each other. In response to a corresponding block selection signal, data may be read from or written in a selected memory block among the plurality of memory blocks BLK1 to BLKz. The program operation or the read operation on the memory cells of the memory cell array 110 may be performed in units of page. Also, the erase operation on the memory cells of the memory cell array 110 may be performed in units of memory block. Each of the plurality of memory blocks BLK1 to BLKz may include a plurality of cell strings, and the plurality of cell strings may be connected to a plurality of bit lines BL. Each of the plurality of cell strings may include a plurality of cell transistors. The plurality of cell transistors may be connected to string selection lines SSL, word lines WL, and ground selection lines GSL.

For example, the nonvolatile memory device 100 may be a vertical NAND flash memory device. In the case of the vertical NAND flash memory device, the memory blocks BLK1 to BLKz may include a plurality of cell strings formed in a NAND type.

The address decoder 120 may be connected to the memory cell array 110 through the string selection lines SSL, the word lines WL, and the ground selection lines GSL. The address decoder 120 may receive an address from an external device (e.g., a memory controller) and may decode the received address. The address decoder 120 may control the string selection lines SSL, the word lines WL, and the ground selection lines GSL based on the decoded address. For example, under control of the control logic circuit 160, the address decoder 120 may provide various voltages received from the voltage generator 130 to the string selection lines SSL, the word lines WL, and the ground selection lines GSL based on the decoded address.

The voltage generator 130 may generate various voltages necessary for the nonvolatile memory device 100 to operate. For example, the voltage generator 130 may be configured to generate various voltages, which are provided to the string selection lines SSL, the word lines WL, the ground selection lines GSL, or any other components for the operation of the nonvolatile memory device 100, such as a plurality of program voltages, a plurality of program verify voltages, a plurality of pass voltages, a plurality of read voltages, a plurality of read pass voltages, a plurality of erase voltages, a plurality of erase verify voltages, and a plurality of word line erase voltages.

The page buffer 140 may be connected to the memory cell array 110 through bit lines BL and may read information stored in the memory cells. In the program operation, the page buffer 140 may operate as a write driver and may apply a voltage according to data to be stored in the memory cell array 110 to the bit line BL; in the read operation, the page buffer 140 may operate as a sense amplifier and may sense data stored in the memory cell array 110. The page buffer 140 may operate depending to a control signal provided from the control logic circuit 160.

The input/output circuit 150 may be connected to the page buffer 140 through data lines DL and may exchange data “DATA” with the page buffer 140 through the data lines DL. Under control of the control logic circuit 160, the input/output circuit 150 may send the data “DATA” to the external device (e.g., a memory controller) or may receive the data “DATA” from the external device.

The control logic circuit 160 may control various components in response to a command CMD from the external device such that the nonvolatile memory device 100 performs an operation corresponding to the command CMD.

Meanwhile, the remaining components of the nonvolatile memory device 100 other than the memory cell array 110 may be referred to as a “peripheral circuit PERI”.

According to an embodiment of the present disclosure, each of the plurality of memory blocks BLK1 to BLKz may include a plurality of memory cell structures. Each of the plurality of memory cell structures may include a plurality of word lines respectively connected to a plurality of memory cells. The plurality of word lines may be classified into a plurality of word line groups. One word line group may include two or more word lines. Also, word lines included in one word line group may be electrically connected. In an embodiment, word lines included in one word line group may be included in different memory cell structures.

In this case, page data corresponding to one page being the unit of one program operation or one read operation may be stored in memory cells connected to one word line group (or connected to a plurality of word lines). According to the above description, the size (or capacity) of the page may increase, compared to the case where page data are stored in memory cells connected to one word line. Accordingly, a nonvolatile memory device with improved performance and an electronic system including the same may be provided.

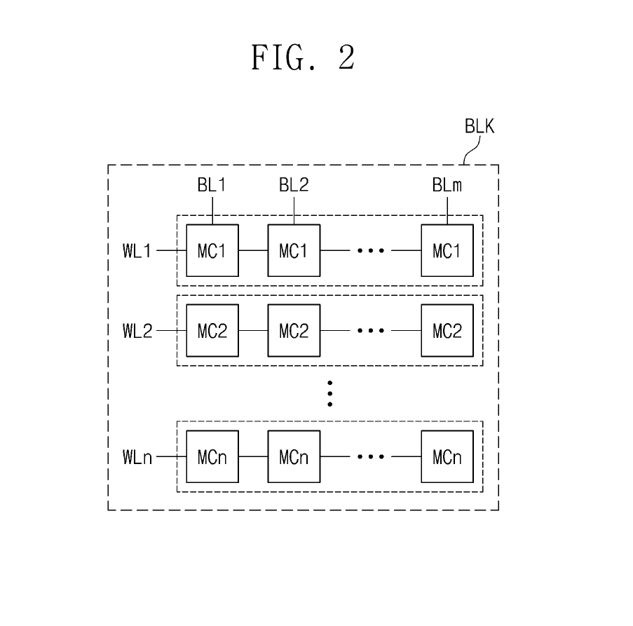

FIG. 2 is a diagram for describing an example of a memory block of FIG. 1. Referring to FIG. 2, a memory block BLK may include a plurality of word lines WL1 to WLn, a plurality of bit lines BL1 to BLm, and a plurality of first to n-th memory cells MC1 to MCn. The first memory cells MC1 may be connected to the first word line WL1 and the plurality of bit lines BL1 to BLm, the second memory cells MC2 may be connected to the second word line WL2 and the plurality of bit lines BL1 to BLm, and the n-th memory cells MCn may be connected to the n-th word line WLn and the plurality of bit lines BL1 to BLm.

Also, memory cells connected to one word line may constitute a page. For example, when each of the memory cells MC1 to MCn is a single level cell (SLC) storing one bit, memory cells connected to one word line may constitute one page. For example, when each of the memory cells MC1 to MCn is a multi-level cell (MLC) storing two bits, memory cells connected to one word line may constitute two pages. For example, when each of the memory cells MC1 to MCn is a triple level cell (TLC) storing three bits, memory cells connected to one word line may constitute three pages. The three pages may include a least significant bit (LSB) page, a center significant bit (CSB) page, and a most significant bit (MSB) page. That is, the number of pages which memory cells connected to one word line constitute may be determined depending on the number of bits stored in each of the memory cells MC1 to MCn.

Meanwhile, the nonvolatile memory device 100 may perform the program operation and the read operation in units of page. In detail, the nonvolatile memory device 100 may perform the program operation or the read operation in units of page by programming (or storing) page data in one page or reading page data stored in one page. That is, the page data may be a minimum program unit and a minimum read unit of the nonvolatile memory device 100.

For example, when each of the memory cells MC1 to MCn is the SLC, the first memory cells MC1 connected to the first word line WL1 may constitute a first page, the second memory cells MC2 connected to the second word line WL2 may constitute a second page, and the n-th memory cells MCn connected to the n-th word line WLn may constitute an n-th page. For example, when each of the memory cells MC1 to MCn is the TLC, the first memory cells MC1 may constitute a first LSB page, a first CSB page, and a first MSB page, the second memory cells MC2 may constitute a second LSB page, a second CSB page, and a second MSB page, and the n-th memory cells MCn may constitute an n-th LSB page, an n-th CSB page, and an n-th MSB page.

In this case, the size (or capacity) of one page and the size of page data may correspond to the number of memory cells connected to one word line or the number of bit lines connected to one page. Accordingly, to increase the size of a page, it may be necessary to increase the length of each of the word lines WL1 to WLn. When the length of the word line increases, a line resistance and a line capacitance of the word line (i.e., the RC load of the word line) may increase. In other words, the reduction of performance of the nonvolatile memory device 100 may be caused by the RC delay. Also, as the length of the word lines WL1 to WLn increases, the area of a semiconductor package including the nonvolatile memory device 100 may increase. This may mean that the size of one page is incapable of being increased to a size larger than a reference size (e.g., 16 kilobytes (KB).

Unlike the example of FIG. 2, according to an embodiment of the present disclosure, page data corresponding to one page may be stored in memory cells connected to a word line group including a plurality of word lines. According to the above description, the size of the page may be increased without the increase in the word line length. Also, the size of the page may be increased without increasing the area of the semiconductor package in a direction in which the word line extends. Accordingly, a nonvolatile memory device with improved performance and an electronic system including the same may be provided. A configuration of a nonvolatile memory device according to an embodiment of the present disclosure will be described in detail with reference to the following drawings.

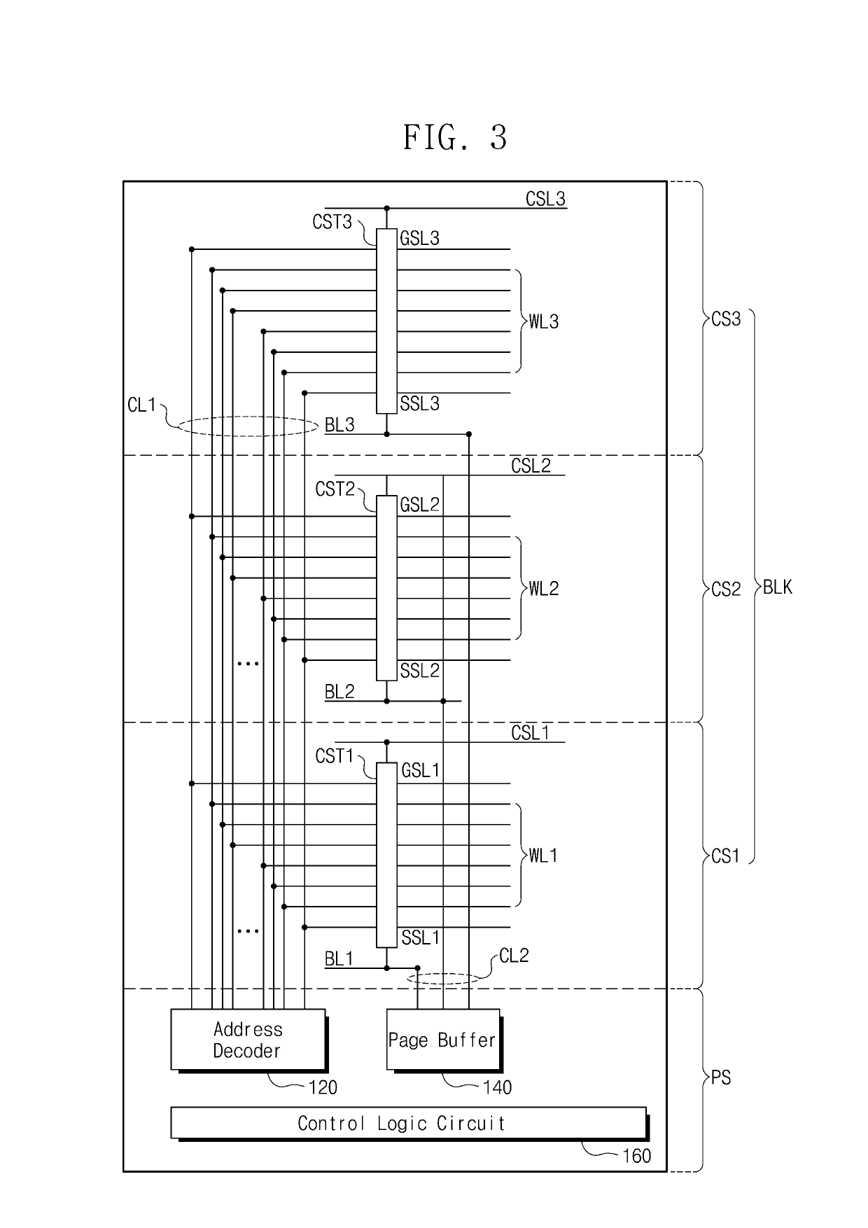

FIG. 3 is a circuit diagram schematically illustrating a nonvolatile memory device of FIG. 1. Referring to FIGS. 1 and 3, a nonvolatile memory device according to embodiments of the present disclosure may include a peripheral circuit structure PS and a plurality of memory blocks BLK formed on the peripheral circuit structure PS.

Each memory block BLK may overlap the peripheral circuit structure PS in a plan view. In embodiments, the peripheral circuit structure PS may include peripheral circuits PERI described with reference to FIG. 1.

Each memory block BLK may include a first memory cell structure CS1 on the peripheral circuit structure PS, a second memory cell structure CS2 on the first memory cell structure CS1, and a third memory cell structure CS3 on the second memory cell structure CS2. An example in which one memory block BLK includes three memory cell structures CS1 to CS3 is illustrated in FIG. 3, but the present disclosure is not limited thereto. That is, the number of memory cell structures included in one memory block BLK may be variously changed.

In an embodiment, the first to third memory cell structures CS1 to CS3 constituting the memory block BLK may be separately manufactured on different wafers and may be then connected to each other by a bonding manner. For example, a bonding metal formed in the uppermost metal layer of the first memory cell structure CS1 may be electrically connected to a bonding metal formed in the lowermost metal layer of the second memory cell structure CS2. Also, a bonding metal formed in the uppermost metal layer of the second memory cell structure CS2 may be electrically connected to a bonding metal formed in the lowermost metal layer of the third memory cell structure CS3. For example, when the bonding metal is formed of copper (Cu), the bonding manner may be referred to as a “Cu-to-Cu bonding manner”. A structure of FIG. 3, in which a plurality of memory cell structures (e.g., CS1 to CS3) are connected by the bonding manner may be referred to as a “cell multi-wafer bonding (CMB) structure”.

An example in which a bit line (e.g., BL1) of a memory cell structure is placed on a lower portion of the memory cell structure (e.g., CS1) is illustrated in FIG. 3, but the present disclosure is not limited thereto. Accordingly, for example, the bit line (e.g., BL1) of the memory cell structure (e.g., CS1) may be placed on a lower portion of the memory cell structure (e.g., CS1). Also, unlike the example illustrated in FIG. 3, the memory block BLK may be implemented such that the bonding metal formed in the uppermost metal layer of the first memory cell structure CS1 is electrically connected to the bonding metal formed in the uppermost metal layer of the second memory cell structure CS2 (i.e., the first memory cell structure CS1 and the second memory cell structure CS2 being bonded such that a first common source line CSL1 and a second common source line CSL2 are close to each other). Also, locations of a bit line (e.g., BL1) and word lines (e.g., WL1) of each of the first to third memory cell structures CS1 to CS3 may be variously changed.

The first to third memory cell structures CS1 to CS3 may include a plurality of cell strings CST1 to CST3.

The first memory cell structure CS1 may include a first bit line BL1, a first string selection line SSL1, first word lines WL1, a first ground selection line GSL1, the first common source line CSL1, and the first cell string CST1. In the first memory cell structure CS1, the first cell string CST1 may be provided in plurality.

The second memory cell structure CS2 may include a second bit line BL2, a second string selection line SSL2, second word lines WL2, a second ground selection line GSL2, the second common source line CSL2, and the second cell string CST2. In the second memory cell structure CS2, the second cell string CST2 may be provided in plurality.

The third memory cell structure CS3 may include a third bit line BL3, a third string selection line SSL3, third word lines WL3, a third ground selection line GSL3, a third common source line CSL3, and the third cell string CST3. In the third memory cell structure CS3, the third cell string CST3 may be provided in plurality.

The first word lines WL1 of the first memory cell structure CS1, the second word lines WL2 of the second memory cell structure CS2, and the third word lines WL3 of the third memory cell structure CS3 may be connected to the address decoder 120 through first connection lines CL1.

The first to third ground selection lines GSL1 to GSL3 of the first to third memory cell structures CS1 to CS3 may be connected to the address decoder 120 through the first connection lines CL1. The first to third string selection lines SSL1 to SSL3 of the first to third memory cell structures CS1 to CS3 may be connected to the address decoder 120 through the first connection lines CL1. The first bit line BL1 of the first memory cell structure CS1 may be connected to the page buffer 140 through a second connection line CL2, the second bit line BL2 of the second memory cell structure CS2 may be connected to the page buffer 140 through the second connection line CL2, and the third bit line BL3 of the third memory cell structure CS3 may be connected to the page buffer 140 through the second connection line CL2.

In an embodiment, cell strings (e.g., CST1 to CST3) placed at the same column may constitute one cell string group. Because the word lines WL1 to WL3, the string selection lines SSL1 to SSL3, the ground selection lines GSL1 to GSL3 are connected through the first connection lines CL1, one cell string group may be managed like one cell string.

Meanwhile, for example, the first common source line CSL1 of the first memory cell structure CS1 may be connected to the peripheral circuit structure PS (e.g., the voltage generator 130) through a third connection line (not illustrated), the second common source line CSL2 of the second memory cell structure CS2 may be connected to the peripheral circuit structure PS (e.g., the voltage generator 130) through the third connection line, and the third common source line CSL3 of the third memory cell structure CS3 may be connected to the peripheral circuit structure PS (e.g., the voltage generator 130) through the third connection line.

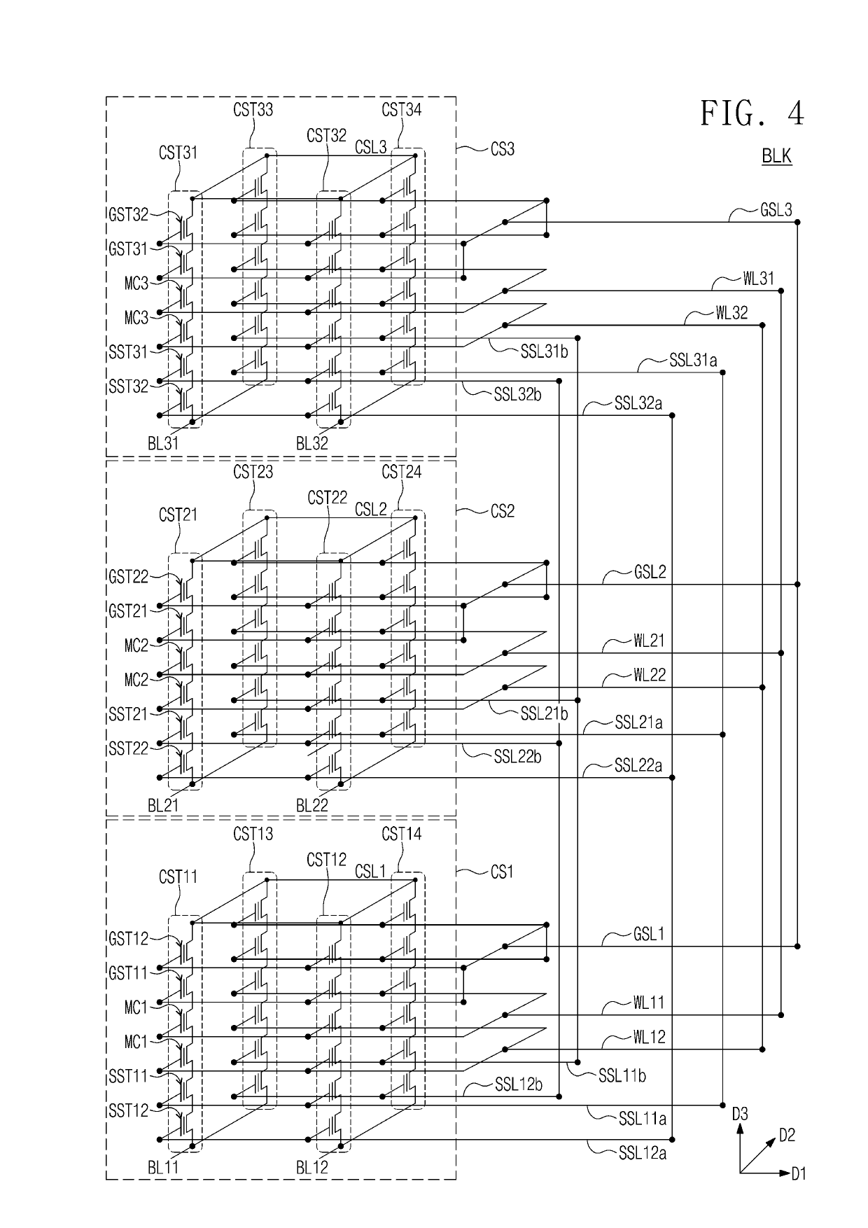

FIG. 4 is a circuit diagram illustrating a memory block of FIG. 1. Referring to FIGS. 1, 3, and 4, the memory block BLK may include the first memory cell structure CS1, the second memory cell structure CS2 on the first memory cell structure CS1, and the third memory cell structure CS3 on the second memory cell structure CS2.

The first memory cell structure CS1 may include the first common source line CSL1, first bit lines BL11 and BL12, and a plurality of first cell strings CST11 to CST14 disposed between the first common source line CSL1 and the first bit lines BL11 and BL12.

The first cell strings CST11 to CST14 may extend along the third direction D3 on the plane extending along the first and second directions D1 and D2. The first cell strings CST11 to CST14 may be arranged in the two-dimensional structure along the first and second directions D1 and D2 crossing each other.

The first bit lines BL11 and BL12 may be spaced apart from each other in the first direction D1 and may extend in the second direction D2.

The first cell strings CST11 to CST14 may be connected in parallel to the first bit lines BL11 and BL12. The first cell strings CST11 to CST14 may be connected in common to the first common source line CSL1. That is, the plurality of first cell strings CST11 to CST14 may be disposed between the plurality of first bit lines BL11 and BL12 and one first common source line CSL1.

In an embodiment, each of the first cell strings CST11 to CST14 may include a plurality of cell transistors. For example, the plurality of cell transistors may include first string selection transistors SST11 and SST12, the first memory cells MC1, and first ground selection transistors GST11 and GST12. The first string selection transistors SST11 and SST12 connected in series may be provided or connected between the first memory cells MC1 and the first bit line BL1. The ground selection transistors GST11 and GST12 connected in series may be provided or connected between the first memory cells MC1 and the first common source line CSL1.

The first memory cells MC1 may be connected in series between the first string selection transistor SST11 and the first ground selection transistor GST11. Each of the plurality of cell transistors may include a charge trap flash (CTF) memory cell, but the present disclosure is not limited thereto.

In each of the plurality of first cell strings CST11 to CST14, memory cells placed at the same height from among the first memory cells MC1 may share the same word line. For example, the first memory cells MC1 respectively included in the plurality of first cell strings CST11 to CST14 may be placed at the same height from a substrate (not illustrated) and may share a first word line WL11. The first memory cells MC1 respectively included in the plurality of first cell strings CST11 to CST14 may be placed at the same height from the substrate (not illustrated) and may share a second word line WL12.

String selection transistors placed at the same height and the same row from among the string selection transistors SST11 and SST12 respectively included in the plurality of first cell strings CST11 to CST14 may share the same string selection line. For example, the string selection transistors SST12 of the first cell strings CST11 and CST12 may be connected to a string selection line SSL12a, and the string selection transistors SST11 of the first cell strings CST11 and CST12 may be connected to a string selection line SSL11a. For example, the string selection transistors SST12 of the first cell strings CST13 and CST14 may be connected to a string selection line SSL12b, and the string selection transistors SST11 of the first cell strings CST13 and CST14 may be connected to a string selection line SSL11b.

Although not illustrated in drawings, string selection transistors placed at the same row from among the string selection transistors SST11 and SST12 respectively included in the plurality of first cell strings CST11 to CST14 may share the same string selection line. For example, the string selection transistors SST11 and SST12 of the cell strings CST11 and CST12 may share a first string selection line, and the string selection transistors SST11 and SST12 of the cell strings CST13 and CST14 may share a second string selection line different from the first string selection line.

The ground selection transistors GST11 and GST12 of each of the plurality of first cell strings CST11 to CST14 may share the first ground selection line GSL1.

The second memory cell structure CS2 may include the second common source line CSL2, second bit lines BL21 and BL22, and a plurality of second cell strings CST21 to CST24 disposed between the second common source line CSL2 and the second bit lines BL21 and BL22.

The second cell strings CST21 to CST24 may extend along the third direction D3 on the plane extending along the first and second directions D1 and D2. The second cell strings CST21 to CST24 may be arranged in the two-dimensional structure along the first and second directions D1 and D2 crossing each other.

The second bit lines BL21 and BL22 may be spaced apart from each other in the first direction D1 and may extend in the second direction D2.

The second cell strings CST21 to CST24 may be connected in parallel to the second bit lines BL21 and BL22. The second cell strings CST21 to CST24 may be connected in common to the second common source line CSL2. That is, the plurality of second cell strings CST21 to CST24 may be disposed between the plurality of second bit lines BL21 and BL22 and one second common source line CSL2.

In an embodiment, each of the second cell strings CST21 to CST24 may include a plurality of cell transistors. For example, the plurality of cell transistors may include second string selection transistors SST21 and SST22, the second memory cells MC2, and second ground selection transistors GST21 and GST22. The second string selection transistors SST21 and SST22 connected in series may be provided or connected between the second memory cells MC2 and the second bit line BL21. The ground selection transistors GST21 and GST22 connected in series may be provided or connected between the second memory cells MC2 and the second common source line CSL2.

The second memory cells MC2 may be connected in series between the second string selection transistor SST21 and the second ground selection transistor GST21. Each of the plurality of second memory cells MC2 may be a charge trap flash (CTF) memory cell, but the present disclosure is not limited thereto.

In each of the plurality of second cell strings CST21 to CST24, memory cells placed at the same height from among the second memory cells MC2 may share the same word line. For example, the second memory cells MC2 respectively included in the plurality of second cell strings CST21 to CST24 may be placed at the same height from the substrate (not illustrated) and may share a first word line WL21. The second memory cells MC2 respectively included in the plurality of second cell strings CST21 to CST24 may be placed at the same height from the substrate (not illustrated) and may share a second word line WL22.

String selection transistors placed at the same height and the same row from among the string selection transistors SST21 and SST22 respectively included in the plurality of second cell strings CST21 to CST24 may share the same string selection line. For example, the string selection transistors SST22 of the second cell strings CST21 and CST22 may be connected to a string selection line SSL22a, and the string selection transistors SST21 of the second cell strings CST21 and CST22 may be connected to a string selection line SSL21a. The string selection transistors SST22 of the second cell strings CST23 and CST24 may be connected to a string selection line SSL22b, and the string selection transistors SST21 of the second cell strings CST23 and CST24 may be connected to a string selection line SSL21b.

Although not illustrated in drawings, string selection transistors placed at the same row from among the string selection transistors SST21 and SST22 respectively included in the plurality of second cell strings CST21 to CST24 may share the same string selection line. For example, the string selection transistors SST21 and SST22 of the cell strings CST21 and CST22 may share a first string selection line, and the string selection transistors SST21 and SST22 of the cell strings CST23 and CST24 may share a second string selection line different from the first string selection line.

The ground selection transistors GST21 and GST22 of each of the plurality of second cell strings CST21 to CST24 may share the second ground selection line GSL2.

The third memory cell structure CS3 may include the third common source line CSL3, third bit lines BL31 and BL32, and a plurality of third cell strings CST31 to CST34 disposed between the third common source line CSL3 and the third bit lines BL31 and BL32.

The third cell strings CST31 to CST34 may extend along the third direction D3 on the plane extending along the first and second directions D1 and D2. The third cell strings CST31 to CST34 may be arranged in the two-dimensional structure along the first and second directions D1 and D2 crossing each other.

The third bit lines BL31 and BL32 may be spaced apart from each other in the first direction D1 and may extend in the second direction D2.

The third cell strings CST31 to CST34 may be connected in parallel to the third bit lines BL31 and BL32. The third cell strings CST31 to CST34 may be connected in common to the third common source line CSL3. That is, the plurality of third cell strings CST31 to CST34 may be disposed between the plurality of third bit lines BL31 and BL32 and one third common source line CSL3.

In an embodiment, each of the third cell strings CST31 to CST34 may include a plurality of cell transistors. For example, the plurality of cell transistors may include third string selection transistors SST31 and SST32, the third memory cells MC3, and third ground selection transistors GST31 and GST32. The third string selection transistors SST31 and SST32 connected in series may be provided or connected between the third memory cells MC3 and the first bit line BL31. The ground selection transistors GST31 and GST32 connected in series may be provided or connected between the third memory cells MC3 and the third common source line CSL3.

The third memory cells MC3 may be connected in series between the third string selection transistor SST31 and the third ground selection transistor GST31. Each of the plurality of third memory cells MC3 may be a charge trap flash (CTF) memory cell, but the present disclosure is not limited thereto.

In each of the plurality of third cell strings CST31 to CST34, memory cells placed at the same height from among the third memory cells MC3 may share the same word line. For example, the third memory cells MC3 respectively included in the plurality of third cell strings CST31 to CST34 may be placed at the same height from the substrate (not illustrated) and may share a first word line WL31. The third memory cells MC3 respectively included in the plurality of third cell strings CST31 to CST34 may be placed at the same height from the substrate (not illustrated) and may share a second word line WL32.

String selection transistors placed at the same height and the same row from among the string selection transistors SST31 and SST32 respectively included in the plurality of third cell strings CST31 to CST34 may share the same string selection line. For example, the string selection transistors SST32 of the third cell strings CST31 and CST32 may be connected to a string selection line SSL32a, and the string selection transistors SST31 of the third cell strings CST31 and CST32 may be connected to a string selection line SSL31a. The string selection transistors SST32 of the third cell strings CST33 and CST34 may be connected to a string selection line SSL32b, and the string selection transistors SST31 of the third cell strings CST33 and CST34 may be connected to a string selection line SSL31b.

Although not illustrated in drawings, string selection transistors placed at the same row from among the string selection transistors SST31 and SST32 respectively included in the plurality of third cell strings CST31 to CST34 may share the same string selection line. For example, the string selection transistors SST31 and SST32 of the cell strings CST31 and CST32 may share a first string selection line, and the string selection transistors SST31 and SST32 of the cell strings CST33 and CST34 may share a second string selection line different from the first string selection line.

The ground selection transistors GST31 and GST32 of each of the plurality of third cell strings CST31 to CST34 may share the third ground selection line GSL3.

In an embodiment, the word lines WL11 and WL12 of the first memory cell structure CS1, the word lines WL21 and WL22 of the second memory cell structure CS2, and the word lines WL31 and WL32 of the third memory cell structure CS3 may be respectively connected to the first connection lines CL1. According to the above description, the first word lines WL11, WL21, and WL31 may be electrically connected by the first connection line CL1, and the second word lines WL12, WL22, and WL32 may be electrically connected by the first connection line CL1. In an embodiment, the electrically connected first word lines WL11, WL21, an WL31 may be referred to as a “first word line group”, and the electrically connected second word lines WL12, WL22, and WL32 may be referred to as a “second word line group”.

The string selection lines SSL11a, SSL12a, SSL11b, and SSL12b of the first memory cell structure CS1, the string selection lines SSL21a, SSL22a, SSL21b, and SSL22b of the second memory cell structure CS2, and the string selection lines SSL31a, SSL32a, SSL31b, and SSL32b of the third memory cell structure CS3 may be connected to each other through the first connection lines CL1.

The first ground selection line GSL1 of the first memory cell structure CS1, the second ground selection line GSL2 of the second memory cell structure CS2, and the third ground selection line GSL3 of the third memory cell structure CS3 may be connected to each other through the first connection lines CL1.

The first bit lines BL11 and BL12 of the first memory cell structure CS1, the second bit lines BL21 and BL22 of the second memory cell structure CS2, and the third bit lines BL31 and BL32 of the third memory cell structure CS3 may be controlled independently of each other.

Meanwhile, in an embodiment, the same word line voltage may be applied to memory cells connected to the same word line group. That is, the memory cell structures CS1 to CS3 may share a word line. As the memory cell structures CS1 to CS3 do not share bit lines and share word lines, the program operation and the read operation on the memory cell structures CS1 to CS3 may be performed independently of each other.

According to an embodiment of the present disclosure, when a memory cell is implemented with the SLC, memory cells connected to one word line group may constitute one page. For example, memory cells connected to the first word lines WL11, WL21, and WL31 of the first word line group may constitute a first page, and memory cells connected to the second word lines WL12, WL22, and WL32 of the second word line group may constitute a second page.

Meanwhile, cell strings placed at the same column may constitute a cell string group. The cell strings CST11, CST21, and CST31 may constitute a first cell string group, the cell strings CST12, CST22, and CST32 may constitute a second cell string group, the cell strings CST13, CST23, and CST33 may constitute a third cell string group, and the cell strings CST14, CST24, and CST34 may constitute a fourth cell string group. In this case, for example, in the read operation on the first page, the first word line group may output data stored in the memory cells MC1, MC2, and MC3 connected to the first word line group through the bit lines BL11, BL21, and BL31.

In an embodiment, the memory block BLK illustrated in FIG. 4 is provided as an example. For example, the number of cell strings may increase or decrease, and the number of rows of cell strings and the number of columns of cell strings may increase or decrease depending on the change in the number of cell strings. Also, the memory block BLK may further include dummy memory cells. The number of cell transistors of the memory block BLK may increase or decrease, and the height of the memory block BLK may increase or decrease depending of the number of cell transistors. In addition, the number of lines connected to the cell transistors may increase or decrease depending on the number of cell transistors. An example in which a bit line (e.g., BL1) of a memory cell structure (e.g., CS1) is placed on a lower portion of the memory cell structure (e.g., CS1) is illustrated in FIG. 4, but the present disclosure is not limited thereto. Locations of a bit line (e.g., BL1) and word lines (e.g., WL1) of each of the memory cell structures CS1 to CS3 may be variously changed.

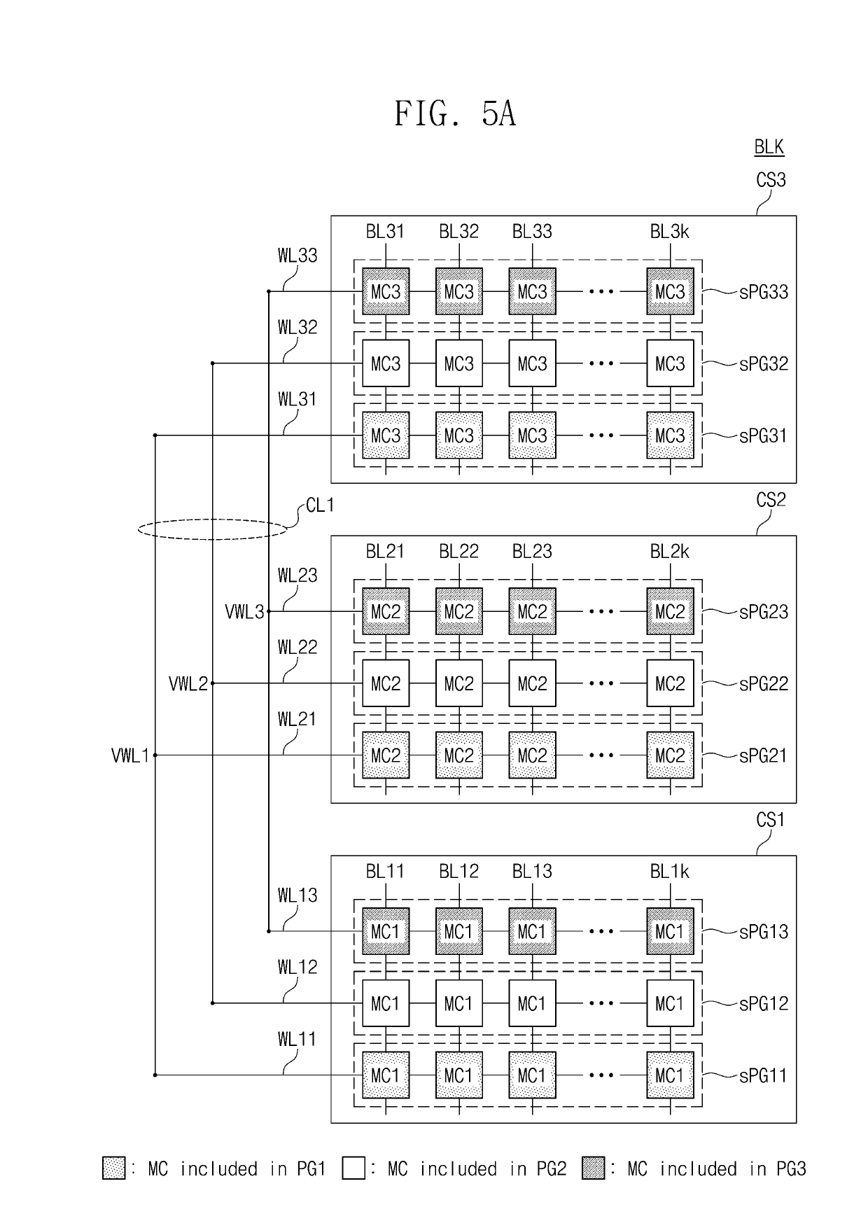

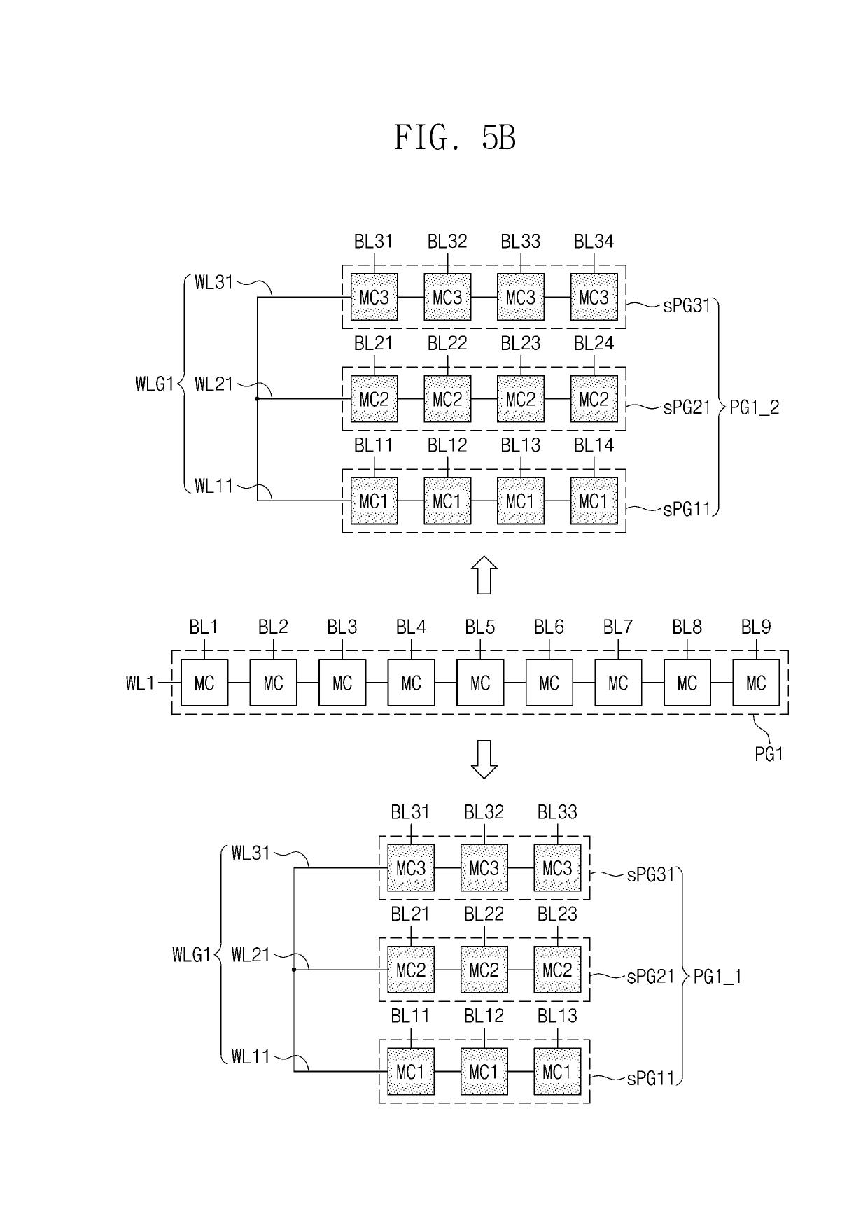

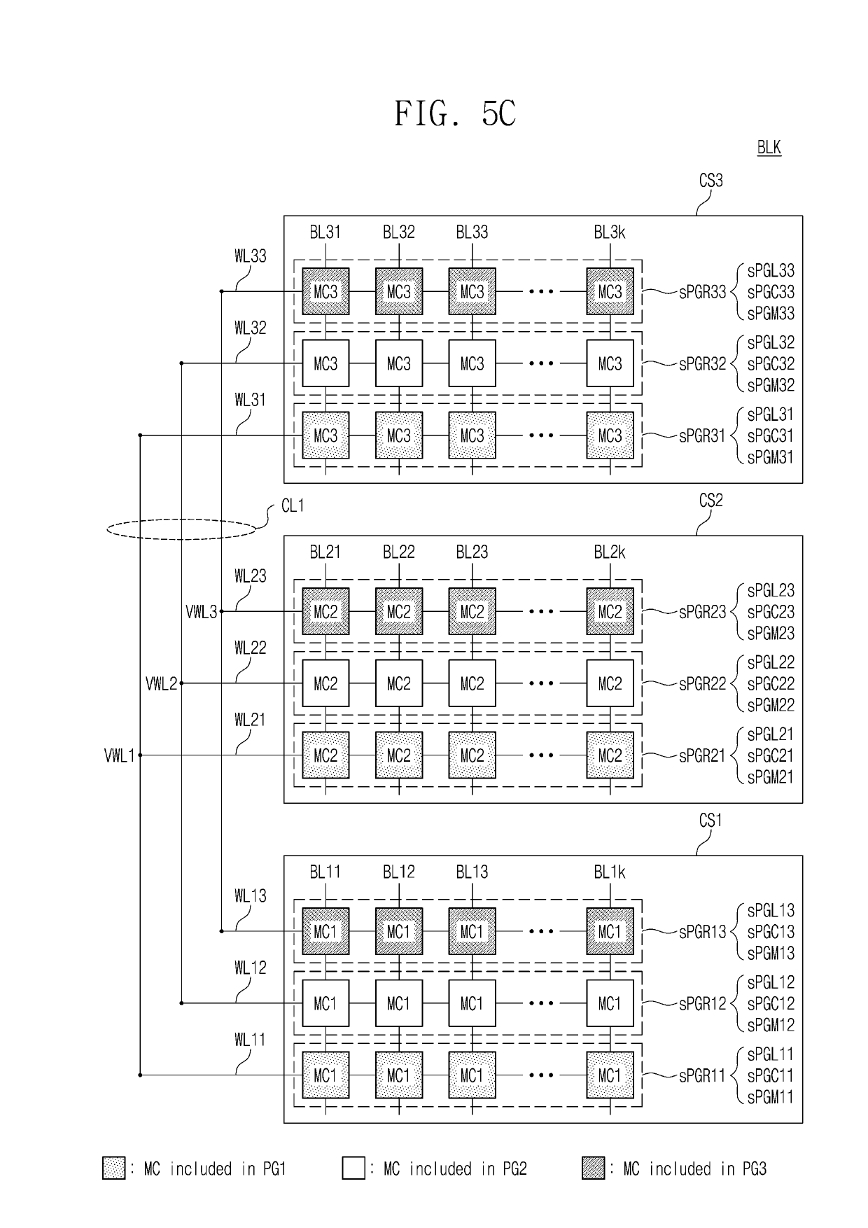

FIGS. 5A to 5C are diagrams for describing a page configuration of a memory cell array of FIG. 1. FIGS. 5A to 5C will be described based on the case where one cell string (e.g., CST11 of FIG. 4) includes three memory cells, but the present disclosure is not limited thereto. Meanwhile, in FIGS. 5A and 5B, it is assumed that the memory cells MC1 to MC3 are implemented with the SLC; in FIG. 5C, it is assumed that the memory cells MC1 to MC3 are implemented with the TLC.

Referring to FIGS. 1 and 3 to 5A, the first memory cell structure CS1 may include the first memory cells MC1 connected to the first to third word lines WL11 to WL13 and a plurality of first bit lines BL11 to BL1k. The second memory cell structure CS2 may include the second memory cells MC2 connected to the first to third word lines WL21 to WL23 and a plurality of second bit lines BL21 to BL2k. The third memory cell structure CS3 may include the third memory cells MC3 connected to the first to third word lines WL31 to WL33 and a plurality of third bit lines BL31 to BL3k.

The first word lines WL11, WL21, and WL31 may be connected through the first connection line CL1 and may be included in a first word line group. The second word lines WL12, WL22, and WL32 may be connected through the first connection line CL1 and may be included in a second word line group. The third word lines WL13, WL23, and WL33 may be connected through the first connection line CL1 and may be included in a third word line group.

The first memory cells MC1 connected to the first word line WL11 of the first memory cell structure CS1 may constitute a first sub-page sPG11, the first memory cells MC1 connected to the second word line WL12 of the first memory cell structure CS1 may constitute a second sub-page sPG12, and the first memory cells MC1 connected to the third word line WL13 of the first memory cell structure CS1 may constitute a third sub-page sPG13.

The second memory cells MC2 connected to the first word line WL21 of the second memory cell structure CS2 may constitute a first sub-page sPG21, the second memory cells MC2 connected to the second word line WL22 of the second memory cell structure CS2 may constitute a second sub-page sPG22, and the second memory cells MC2 connected to the third word line WL23 of the second memory cell structure CS2 may constitute a third sub-page sPG23.

The third memory cells MC3 connected to the first word line WL31 of the third memory cell structure CS3 may constitute a first sub-page sPG31, the third memory cells MC3 connected to the second word line WL32 of the third memory cell structure CS3 may constitute a second sub-page sPG32, and the third memory cells MC3 connected to the third word line WL33 of the third memory cell structure CS3 may constitute a third sub-page sPG33.

In an embodiment, the sub-pages sPG11 to sPG13, sPG21 to sPG23, and sPG31 to sPG33 may have the same size.

A first word line voltage VWL1 may be applied to the first word line group, a second word line voltage VWL2 may be applied to the second word line group, and a third word line voltage VWL3 may be applied to the third word line group. Also, memory cells connected to the first word line group may constitute a first page PG1, memory cells connected to the second word line group may constitute a second page PG2, and memory cells connected to the third word line group may constitute a third page PG3.

That is, the first page PG1 may include the first sub-pages sPG11, sPG21, and sPG31 included in the first to third memory cell structures CS1 to CS3. The second page PG2 may include the second sub-pages sPG12, sPG22, and sPG32 included in the first to third memory cell structures CS1 to CS3. The third page PG3 may include the third sub-pages sPG13, sPG23, and sPG33 included in the first to third memory cell structures CS1 to CS3.

That is, the first memory cells MC1 of the first sub-page sPG11 may store first sub-page data included in first page data corresponding to the first page PG1, the second memory cells MC2 of the first sub-page sPG21 may store second sub-page data included in the first page data corresponding to the first page PG1, and the third memory cells MC3 of the first sub-page sPG31 may store third sub-page data included in the first page data corresponding to the first page PG1.

The first memory cells MC1 of the second sub-page sPG12 may store first sub-page data included in second page data corresponding to the second page PG2, the second memory cells MC2 of the second sub-page sPG22 may store second sub-page data included in the second page data corresponding to the second page PG2, and the third memory cells MC3 of the second sub-page sPG32 may store third sub-page data included in the second page data corresponding to the second page PG2.

The first memory cells MC1 of the third sub-page sPG13 may store first sub-page data included in third page data corresponding to the third page PG3, the second memory cells MC2 of the third sub-page sPG23 may store second sub-page data included in the third page data corresponding to the third page PG3, and the third memory cells MC3 of the third sub-page sPG33 may store third sub-page data included in the third page data corresponding to the third page PG3.

Referring to FIG. 5B, unlike the above description, as exemplified in FIG. 2, the first page PG1 may be composed of nine memory cells MC connected to the first word line WL1. In this case, a speed at which the program operation or the read operation on the first page PG1 is performed may become slower due to the RC delay caused by the first word line WL1. Also, because it is impossible to further increase the length of the first word line WL1, it may also be impossible to increase the size of the first page PG1 any longer.

In contrast, according to an embodiment of the present disclosure, a first page PG1_1 may be composed of nine memory cells connected to a first word line group WLG1. In this case, each of the first sub-pages sPG11 to sPG31 may include three memory cells. According to the above description, the length of each of the word lines WL11, WL21, and WL31 may be shorter than the length of the first word line WL1, and thus, the RC delay caused by each of the word lines WL11, WL21, and WL31 may decrease. This may mean that the program or read operation speed of the first page PG1_1 becomes higher.

Alternatively, a first page PG1_2 may be composed of 12 memory cells connected to the first word line group WLG1. In this case, the length of each of the word lines WL11, WL21, and WL31 may be shorter than the length of the first word line WL1. This may mean that the program or read operation speed of the first page PG1_2 becomes higher. Also, each of the first sub-pages sPG11 to sPG31 may include four memory cells, and thus, the size (or capacity) of the first page PG1 may increase. In this case, the data throughput of the nonvolatile memory device 100 per unit time may increase.

Referring to FIG. 5C, when the memory cells MC1 to MC3 are implemented with the TLC, the memory cells MC1 to MC3 connected to the first word lines WL11, WL21, and WL31 of the first word line group may constitute a first page group PGR1. The first page group PGR1 may include a first LSB page, a first CSB page, and a first MSB page. Also, the memory cells MC1 to MC3 connected to the second word lines WL12, WL22, and WL32 of the second word line group may constitute a second page group PGR2. The second page group PGR2 may include a second LSB page, a second CSB page, and a second MSB page. In addition, the memory cells MC1 to MC3 connected to the third word lines WL13, WL23, and WL33 of the third word line group may constitute a third page group PGR3. The third page group PGR3 may include a third LSB page, a third CSB page, and a third MSB page.

The first memory cells MC1 connected to the first word line WL11 of the first memory cell structure CS1 may constitute a first sub-page group sPGR11, the first memory cells MC1 connected to the second word line WL12 of the first memory cell structure CS1 may constitute a second sub-page group sPGR12, and the first memory cells MC1 connected to the third word line WL13 of the first memory cell structure CS1 may constitute a third sub-page group sPGR13. The sub-page groups sPGR11, sPGR12, and sPGR13 may include LSB sub-pages sPGL11, sPGL12, and sPGL13, CSB sub-pages sPGC11, sPGC12, and sPGC13, and MSB sub-pages sPGM11, sPGM12, and sPGM13. For example, the first sub-page group sPGR11 may include the first LSB sub-page sPGL11, the first CSB sub-page sPGC11, and the first MSB sub-page sPGM11.

The second memory cells MC2 connected to the first word line WL21 of the second memory cell structure CS2 may constitute a first sub-page group sPGR21, the second memory cells MC2 connected to the second word line WL22 of the second memory cell structure CS2 may constitute a second sub-page group sPGR22, and the second memory cells MC2 connected to the third word line WL23 of the second memory cell structure CS2 may constitute a third sub-page group sPGR23. The sub-page groups sPGR21, sPGR22, and sPGR23 may include LSB sub-pages sPGL21, sPGL22, and sPGL23, CSB sub-pages sPGC21, sPGC22, and sPGC23, and MSB sub-pages sPGM21, sPGM22, and sPGM23. For example, the first sub-page group sPGR21 may include the first LSB sub-page sPGL21, the first CSB sub-page sPGC21, and the first MSB sub-page sPGM21.

The third memory cells MC3 connected to the first word line WL31 of the third memory cell structure CS3 may constitute a first sub-page group sPGR31, the third memory cells MC3 connected to the second word line WL32 of the third memory cell structure CS3 may constitute a second sub-page group sPGR32, and the third memory cells MC3 connected to the third word line WL33 of the third memory cell structure CS3 may constitute a third sub-page group sPGR33. The sub-page groups sPGR31, sPGR32, and sPGR33 may include LSB sub-pages sPGL31, sPGL32, and sPGL33, CSB sub-pages sPGC31, sPGC32, and sPGC33, and MSB sub-pages sPGM31, sPGM32, and sPGM33. For example, the first sub-page group sPGR31 may include the first LSB sub-page sPGL31, the first CSB sub-page sPGC31, and the first MSB sub-page sPGM31.

Accordingly, the first page group PGR1 may include the first sub-page groups sPGR11, sPGR21, and sPGR31. In the first page group PGR1, a first LSB page may include the first LSB sub-pages sPGL11, sPGL21, and sPGL31, a first CSB page may include the first CSB sub-pages sPGC11, sPGC21, and sPGC31, and a first MSB page may include the first MSB sub-pages sPGM11, sPGM21, and sPGM31.

Also, the second page group PGR2 may include the second sub-page groups sPGR12, sPGR22, and sPGR32. In the second page group PGR2, a second LSB page may include the second LSB sub-pages sPGL12, sPGL22, and sPGL32, a second CSB page may include the second CSB sub-pages sPGC12, sPGC22, and sPGC32, and a second MSB page may include the second MSB sub-pages sPGM12, sPGM22, and sPGM32.

Also, the third page group PGR3 may include the third sub-page groups sPGR13, sPGR23, and sPGR33. In the third page group PGR3, a third LSB page may include the third LSB sub-pages sPGL13, sPGL23, and sPGL33, a third CSB page may include the third CSB sub-pages sPGC13, sPGC23, and sPGC33, and a third MSB page may include the third MSB sub-pages sPGM13, sPGM23, and sPGM33.

Each of sub-pages may store sub-page data being a portion of page data corresponding to a page in which the relevant sub-page is included. For example, the first memory cells MC1 of the first LSB sub-page sPGL11 may store first LSB sub-page data being a portion of first LSB page data corresponding to a first LSB page, the second memory cells MC2 of the first LSB sub-page sPGL21 may store second LSB sub-page data being a portion of the first LSB page data, and the third memory cells MC3 of the first LSB sub-page sPGL31 may store third LSB sub-page data being a portion of the first LSB page data.

As described above, according to an embodiment of the present disclosure, page data corresponding to one page may be stored in memory cells which are included in different memory cell structures and are connected to the same word line group. According to the above description, the size of the page may be increased without increasing the area of the of the nonvolatile memory device 100 in a direction in which the word line extends. Accordingly, a nonvolatile memory device with improved performance and an electronic system including the same may be provided.

Meanwhile, the case where a memory cell is implemented with the SLC is illustrated in FIGS. 5A and 5B, and the case where a memory cell is implemented with the TLC is illustrated in FIG. 5C. However, the present disclosure is not limited thereto. For example, the number of pages implemented by memory cells connected to the same word line group may be variously changed.

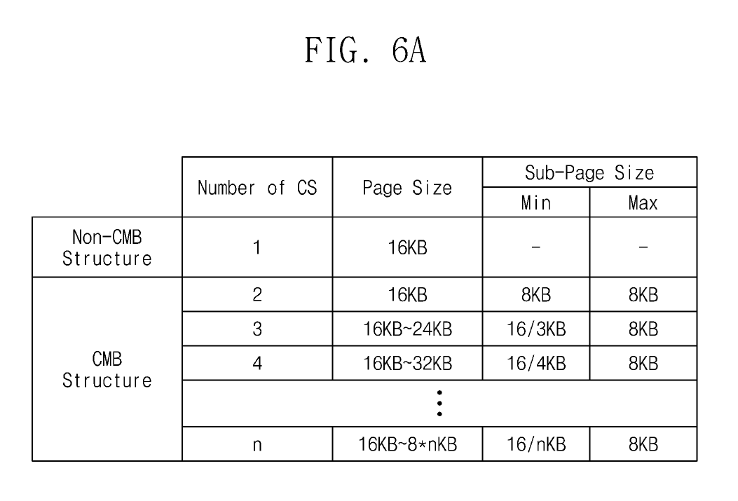

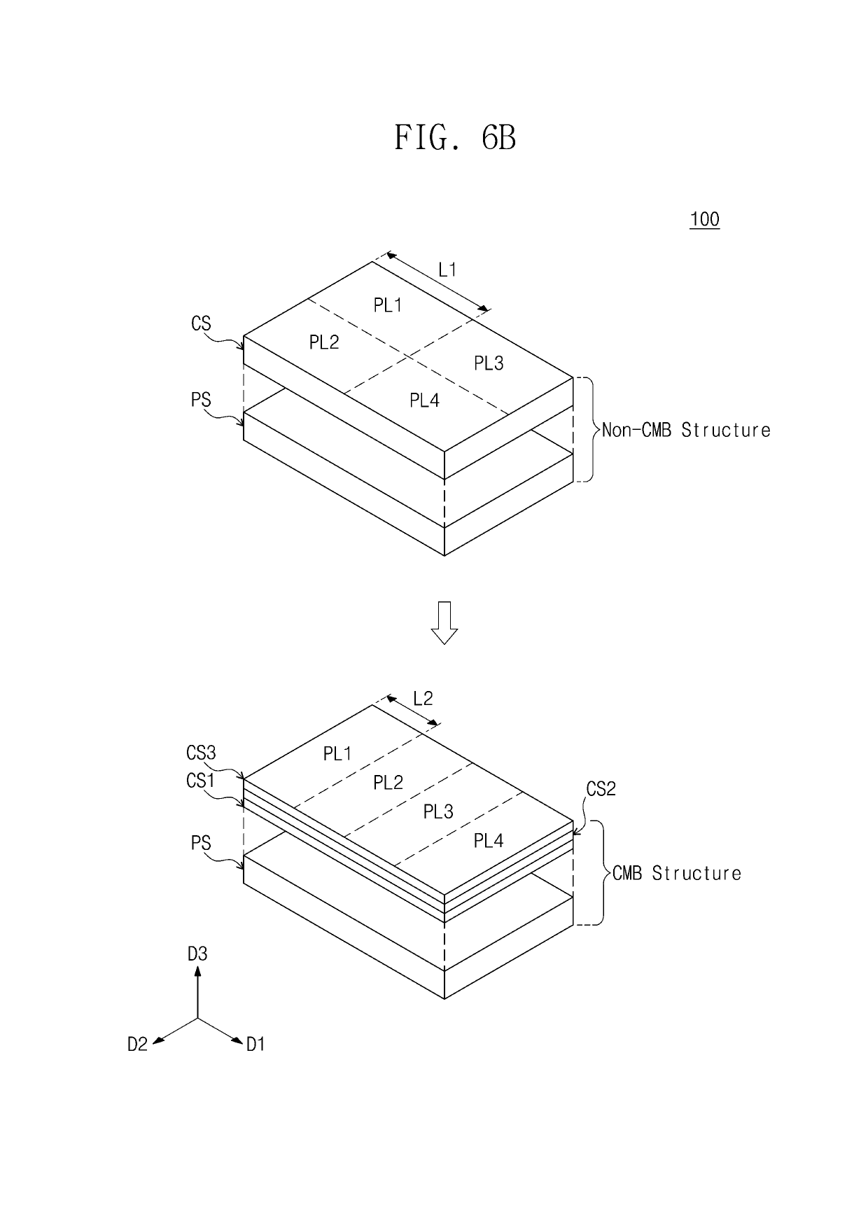

FIGS. 6A and 6B are diagrams for describing a page size of a nonvolatile memory device according to an embodiment of the present disclosure. FIGS. 6A and 6B will be described with reference to FIGS. 1 and 3 to 5A. FIG. 6A shows a table for describing a page size according to the number of memory cell structures, and FIG. 6B schematically shows examples of an exploded perspective view of the nonvolatile memory device 100 of FIG. 1. Referring to FIG. 6A, like the example of FIG. 2, the memory cell array 110 may include only one memory cell structure CS (i.e., the memory cell array 110 being not implemented in the CMB structure) (Non-CMB). This may mean that one page may be composed of memory cells connected to one word line. In this case, according to the issues due to the increase in the word line length, one page may have the maximum size of 16 KB.

Meanwhile, according to an embodiment of the present disclosure, the memory cell array 110 may be implemented in the CMB structure which is formed by bonding a plurality of memory cell structures CS. Also, one page may include a plurality of sub-pages included in different memory cell structures CS.

For example, the memory cell array 110 of the CMB structure may include two memory cell structures CS. In this case, the minimum size and the maximum size of one sub-page (e.g., sPG11) may be 8 KB. According to the above description, the size of one page may be 16 KB.

For example, the memory cell array 110 of the CMB structure may include three memory cell structures CS. In this case, the minimum size of one sub-page (e.g., sPG11) may be (16/3) KB, and the maximum size thereof may be 8 KB. According to the above description, the size of the page (e.g., PG1) may be larger than or equal to 16 KB and may be smaller than or equal to 24 KB.

For example, the memory cell array 110 of the CMB structure may include four memory cell structures CS. In this case, the minimum size of one sub-page (e.g., sPG11) may be 4 KB, and the maximum size thereof may be 8 KB. According to the above description, the size of the page (e.g., PG1) may be larger than or equal to 16 KB and may be smaller than or equal to 32 KB.

That is, for example, the memory cell array 110 of the CMB structure may include “n” memory cell structures CS. In this case, the minimum size of one sub-page (e.g., sPG11) may be (16/n) KB, and the maximum size thereof may be 8 KB. According to the above description, the size of the page (e.g., PG1) may be larger than or equal to (16/n) KB and may be smaller than or equal to 8n KB.

Referring to FIG. 6B, for example, the nonvolatile memory device 100 may include one memory cell structure CS and the peripheral circuit structure PS (i.e., the nonvolatile memory device 100 being implemented in a Non-CMB structure). In this case, the memory cell structure CS may include first to fourth planes PL1 to PL4. Each of the first to fourth planes PL1 to PL4 may include the plurality of memory blocks BLK implemented as illustrated in FIG. 2. The first to fourth planes PL1 to PL4 may be arranged, for example, in the form of a matrix with two rows and two columns.. In this case, for example, the length of each of the first to fourth planes PL1 to PL4 in the first direction D1 may be a first length L1. Meanwhile, as the length of a word line (e.g., WL1 of FIG. 2) connected to one page becomes longer, the first length L1 may become longer. For example, the first length L1 may correspond to the length of the word line (e.g., WL1 of FIG. 2) corresponding to the page of 16 KB.

Unlike the above description, the nonvolatile memory device 100 according to an embodiment of the present disclosure may include the first to third memory cell structures CS1 to CS3 and the peripheral circuit structure PS. The first to third memory cell structures CS1 to CS3 may include the first to fourth planes PL1 to PL4. Each of the first to fourth planes PL1 to PL4 may include the plurality of memory blocks BLK implemented as illustrated in FIG. 4.

The first to fourth planes PL1 to PL4 may be arranged, for example, in the form of a matrix with one row and four columns. In this case, for example, the length of each of the first to fourth planes PL1 to PL4 in the first direction D1 may be a second length L2. Meanwhile, as the length of a word line (e.g., WL11 of FIG. 5A) connected to one page (e.g., sPG11) becomes longer, the second length L2 may become longer.

For example, when the size of one sub-page (e.g., sPG11) is larger than 8 KB, the area (e.g., the chip size) of the nonvolatile memory device 100 implemented in the CMB structure may be larger than the area of a nonvolatile memory device not implemented in the CMB structure. Also, in the nonvolatile memory device 100 including the “n” memory cell structures CS, when the size of one sub-page (e.g., sPG11) is smaller than (16/n) KB, the size of one page (e.g., PG1 of FIG. 5A) may be smaller than 16 KB (i.e., the page size being small compared to the nonvolatile memory device implemented in the Non-CMB structure).

Accordingly, according to an embodiment of the present disclosure, when the nonvolatile memory device 100 includes the “n” memory cell structures CS, as illustrated in FIG. 6A, the size of one sub-page (e.g., sPG11) may be (16/n) KB or more or may be 8 KB or less. According to the above description, it may be possible to increase the page size without increasing the area of the nonvolatile memory device 100 in the first direction D1 (i.e., without increasing the chip size).

Meanwhile, the size of page data stored in a page may be the same as the size of the page, and the size of sub-page data stored in a sub-page may be the same as the size of the sub-page. Accordingly, according to an embodiment of the present disclosure, when the nonvolatile memory device 100 includes the “n” memory cell structures CS, the size of sub-page data stored in one sub-page may be (16/n) KB or more and may be 8 KB or less.

In another embodiment, unlike the above description, the first to fourth planes PL1 to PL4 of the nonvolatile memory device 100 including a plurality of memory cell structures may be arranged in the form of a matrix form different from the matrix with one row and four columns. Accordingly, the maximum size of one sub-page (e.g., sPG11) may be larger than 8 KB. In this case, the size of the page of the nonvolatile memory device 100 including two memory cell structures may be larger than 16 KB.

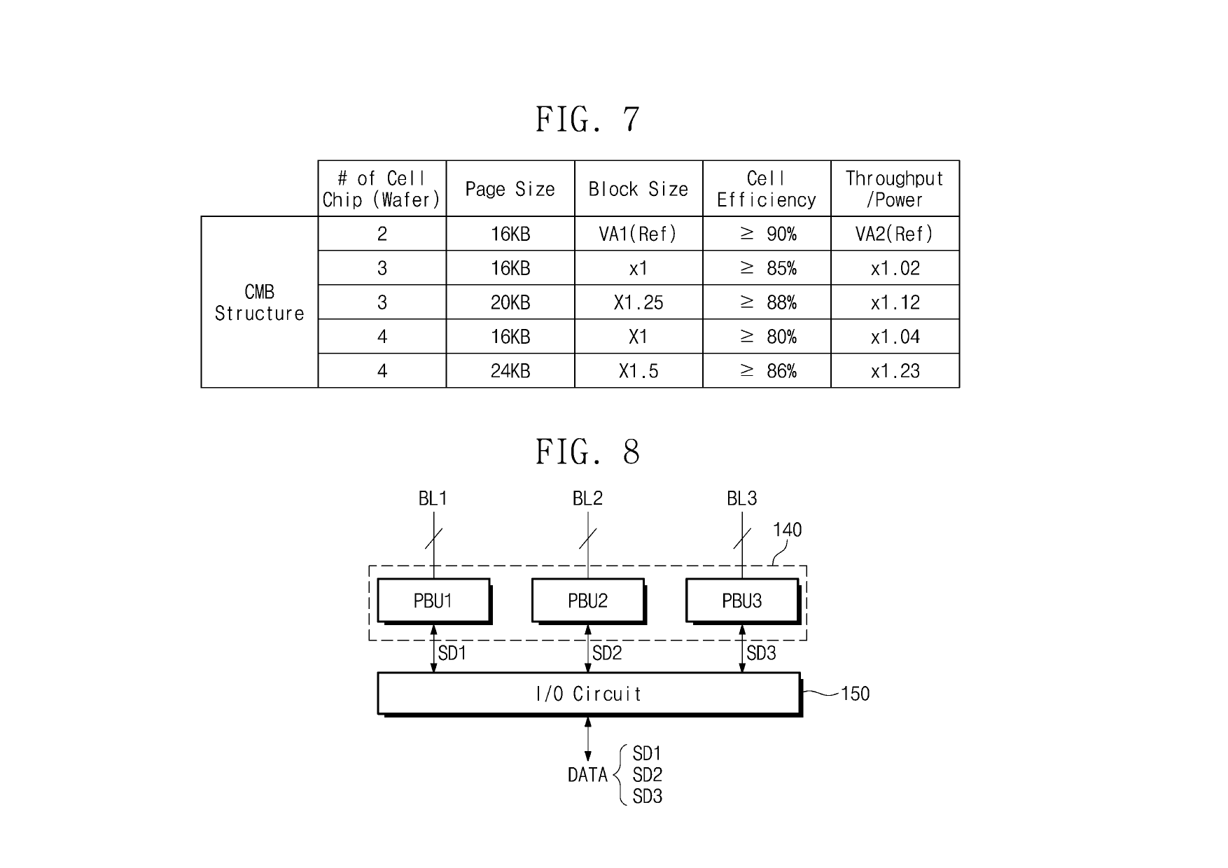

FIG. 7 is a diagram for describing a characteristic according to a page configuration of a nonvolatile memory device of FIG. 1. Referring to FIGS. 1 and 3 to 7, for example, the memory cell array 110 may be implemented in the CMB structure including two memory cell structures CS, and the page size may be 16 KB. In this case, the size of each of the sub-pages of the memory cell array 110 may be 8 KB. Also, the cell efficiency of the nonvolatile memory device 100 may be 90%, the block size may be a first value VA1, and the throughput/power may be a second value VA2.

For example, the memory cell array 110 may be implemented in the CMB structure including three memory cell structures CS, and the page size may be 16 KB. In this case, the size of each of the sub-pages of the memory cell array 110 may be (8/3) KB. Also, the cell efficiency of the nonvolatile memory device 100 may be 85%, the block size may be a value the same as the first value VA1, and the throughput/power may be a value greater than the second value VA2 (e.g., a value increased from the second value VA2 as much as 2%).

For example, the memory cell array 110 may be implemented in the CMB structure including three memory cell structures CS, and the page size may be 20 KB. In this case, the size of each of the sub-pages of the memory cell array 110 may be (20/3) KB. Also, the cell efficiency of the nonvolatile memory device 100 may be 88%, the block size may be a value greater than the first value VA1 (e.g., a value increased from the first value VA1 as much as 25%), and the throughput/power may be a value greater than the second value VA2 (e.g., a value increased from the second value VA2 as much as 12%).

For example, the memory cell array 110 may be implemented in the CMB structure including four memory cell structures CS, and the page size may be 16 KB. In this case, the size of each of the sub-pages of the memory cell array 110 may be 4 KB. Also, the cell efficiency of the nonvolatile memory device 100 may be 80%, the block size may be a value the same as the first value VA1, and the throughput/power may be a value greater than the second value VA2 (e.g., a value increased from the second value VA2 as much as 4%).

For example, the memory cell array 110 may be implemented in the CMB structure including four memory cell structures CS, and the page size may be 24 KB. In this case, the size of each of the sub-pages of the memory cell array 110 may be 6 KB. Also, the cell efficiency of the nonvolatile memory device 100 may be 86%, the block size may be a value greater than the first value VA1 (e.g., a value increased from the first value VA1 as much as 50%), and the throughput/power may be a value greater than the second value VA2 (e.g., a value increased from the second value VA2 as much as 23%).

As described above, according to an embodiment of the present disclosure, as the memory cell array 110 includes a plurality of memory cell structures CS and a page is implemented based on memory cells connected to a word line group, without the degradation of performance, the page size may be increased, and the performance of the throughput/power may be improved.

FIG. 8 is a block diagram for describing a page buffer of FIG. 1. Referring to FIGS. 1 and 3 to 8, the page buffer 140 may include first to third page buffer units PBU1 to PBU3. The first page buffer unit PBU1 may be connected to the first bit lines BL1, the second page buffer unit PBU2 may be connected to the second bit lines BL2, and the third page buffer unit PBU3 may be connected to the third bit lines BL3.

The first bit lines BL1 may be bit lines (e.g., BL11 to BL1k of FIG. 5A) connected to the first memory cells MC1 of the first memory cell structure CS1. The second bit lines BL2 may be bit lines (e.g., BL21 to BL2k of FIG. 5A) connected to the second memory cells MC2 of the second memory cell structure CS2. The third bit lines BL3 may be bit lines (e.g., BL31 to BL3k of FIG. 5A) connected to the third memory cells MC3 of the third memory cell structure CS3.

For example, in the read operation on a first page (e.g., PG1 of FIG. 5A), the first page buffer unit PBU1 may read first sub-page data DATA_s1 stored in a first sub-page (e.g., sPG1 of FIG. 5A), the second page buffer unit PBU2 may read second sub-page data DATA_s2 stored in a second sub-page (e.g., sPG2 of FIG. 5A), and the third page buffer unit PBU3 may read third sub-page data DATA_s3 stored in a third sub-page (e.g., sPG3 of FIG. 5A). The page buffer units PBU1 to PBU3 may transmit the first to third sub-page data DATA_s1 to DATA_s3 to the input/output circuit 150.

For example, in the program operation on the first page PG1, the first page buffer unit PBU1 may program the first sub-page data DATA_s1 in a first sub-page (e.g., sPG1 of FIG. 5A), the second page buffer unit PBU2 may program the second sub-page data DATA_s2 in a second sub-page (e.g., sPG2 of FIG. 5A), and the third page buffer unit PBU3 may program the third sub-page data DATA_s3 in a third sub-page (e.g., sPG3 of FIG. 5A).

In the read operation, the input/output circuit 150 may transmit page data PG_DATA including the plurality of sub-page data DATA_s1 to DATA_s3 received from the page buffer 140 to the external device (e.g., a controller).

In the program operation, the input/output circuit 150 may receive the page data PG_DATA from the external device (e.g., a controller). In this case, the input/output circuit 150 may transmit the first sub-page data DATA_s1 to the first page buffer unit PBU1, may transmit the second sub-page data DATA_s2 to the second page buffer unit PBU2, and may transmit the third sub-page data DATA_s3 to the third page buffer unit PBU3.

As described above, according to an embodiment of the present disclosure, the page buffer 140 may include the page buffer units PBU1 to PBU3 respectively connected to the memory cell structures CS1 to CS3. According to the above description, for example, in the read or program operation on the first page PG1, the page buffer 140 may simultaneously read the plurality of sub-page data DATA_s1 to DATA_s3 stored in the first to third sub-pages (e.g., sPG1 to sPG3 of FIG. 5A) or may write the plurality of sub-page data DATA_s1 to DATA_s3 in the first to third sub-pages (e.g., sPG1 to sPG3 of FIG. 5A).

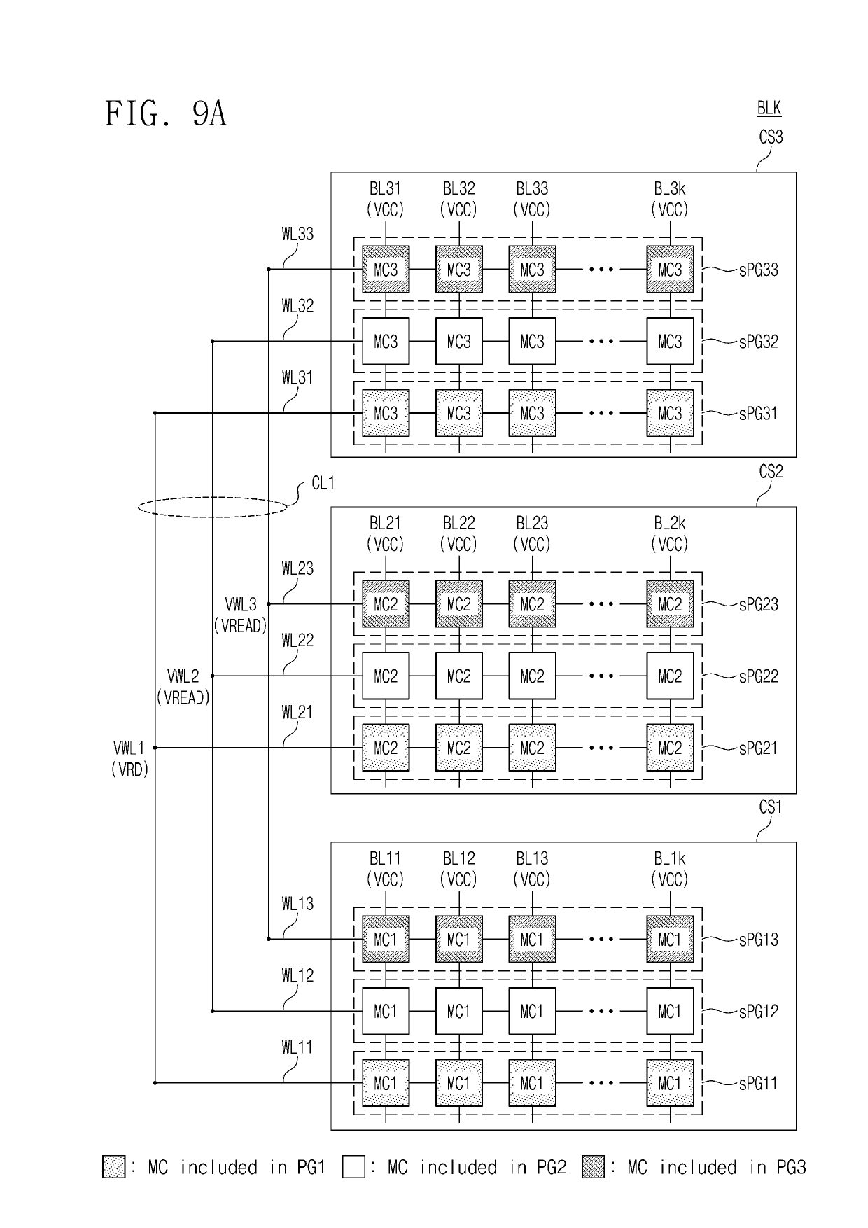

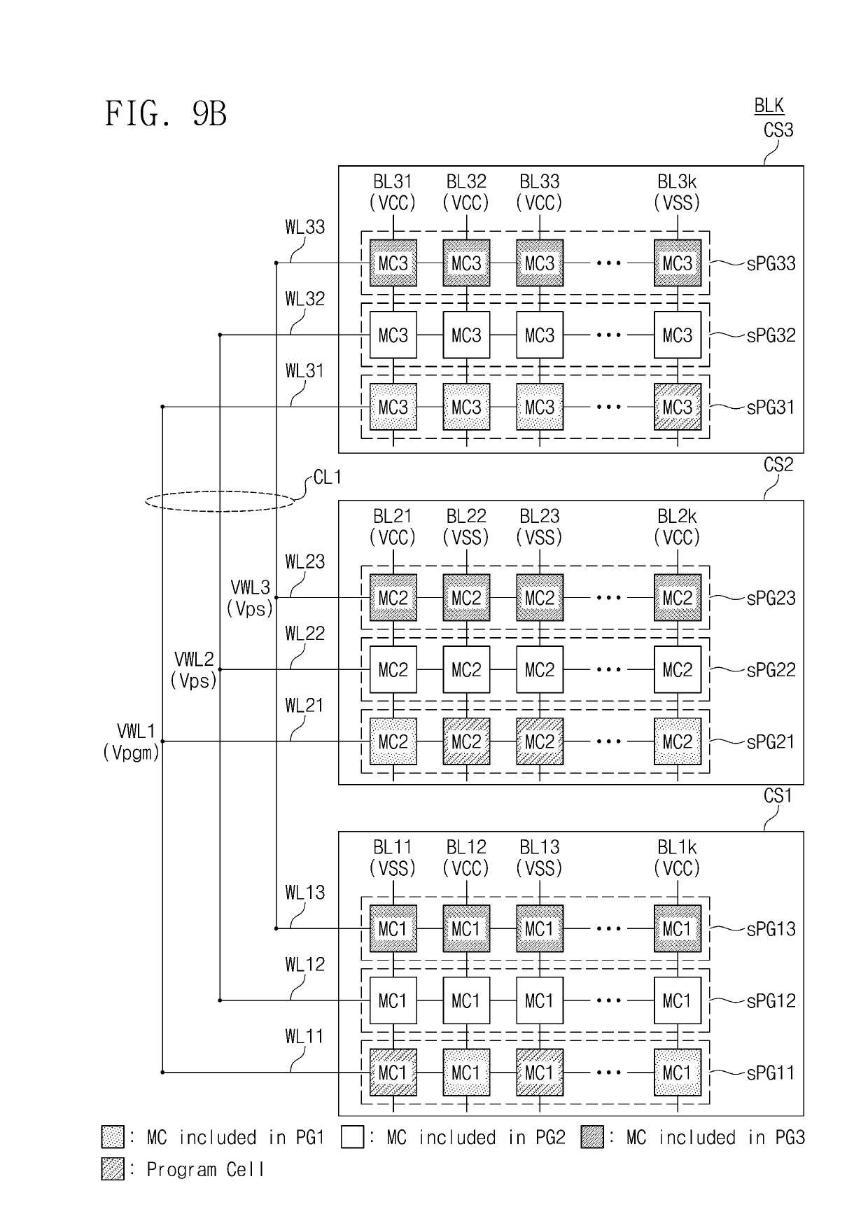

FIGS. 9A and 9B are diagrams for describing an example of a read operation and a program operation of a nonvolatile memory device of FIG. 1. FIGS. 9A and 9B will be described based on the case where the memory cells MC1 to MC3 are implemented with the SLC. Meanwhile, FIG. 9A is a diagram for describing the read operation on the first page PG1, and FIG. 9B is a diagram for describing the program operation on the first page PG1.

Referring to FIGS. 1 and 3 to 9A, in the read operation on the first page PG1, the first word line voltage VWL1 which is applied to the first word line group including the first word lines WL11, WL21, and WL31 may be a read voltage VRD, the second word line voltage VWL2 which is applied to the second word line group including the second word lines WL12, WL22, and WL32 may be a read pass voltage VREAD, and the third word line voltage VWL3 which is applied to the third word line group including the third word lines WL13, WL23, and WL33 may be the read pass voltage VREAD. Also, the first bit lines BL11 to BL1k, the second bit lines BL21 to BL2k, and the third bit lines BL31 to BL3k may be pre-charged with a power supply voltage VCC.

According to the above description, the first sub-page data stored in the first sub-page sPG11 of the first memory cell structure CS1 may be read through the first bit lines BL11 to BL1k, the second sub-page data stored in the first sub-page sPG21 of the second memory cell structure CS2 may be read through the second bit lines BL21 to BL2k, and the third sub-page data stored in the first sub-page sPG31 of the third memory cell structure CS3 may be read through the third bit lines BL31 to BL3k. In an embodiment, the read operations on the first to third sub-page data may be simultaneously performed. That is, the nonvolatile memory device 100 may perform the read operation in units of page data stored in the same word line group.

Referring to FIGS. 1 and 3 to 9B, in the program operation on the first page PG1, the first word line voltage VWL1 which is applied to the first word line group including the first word lines WL11, WL21, and WL31 may be a program voltage Vpgm, the second word line voltage VWL2 which is applied to the second word line group including the second word lines WL12, WL22, and WL32 may be a pass voltage Vps, and the third word line voltage VWL3 which is applied to the third word line group including the third word lines WL13, WL23, and WL33 may be the pass voltage Vps. Also, a ground voltage VSS may be applied to bit lines, which correspond to program cells whose threshold voltages are to be increased, from among the first bit lines BL11 to BL1k, the second bit lines BL21 to BL2k, and the third bit lines BL31 to BL3k, and the power supply voltage VCC may be applied to bit lines corresponding to program inhibit cells.

According to the above description, the first sub-page data may be programmed in the first sub-page sPG11 of the first memory cell structure CS1, the second sub-page data may be programmed in the first sub-page sPG21 of the second memory cell structure CS2, and the third sub-page data may be programmed in the first sub-page sPG31 of the third memory cell structure CS3. In an embodiment, the program operations on the first to third sub-page data may be simultaneously performed. That is, the nonvolatile memory device 100 may program the page data in memory cells connected to the same word line. That is, the nonvolatile memory device 100 may perform the program operation in units of page data including a plurality of sub-page data programmed in different memory cell structures.

As described above, according to an embodiment of the present disclosure, memory cells included in different memory cell structures may share a word line and may not share a bit line. Accordingly, the memory cells included in different memory cell structures may constitute one page (e.g., PG1). The nonvolatile memory device 100 may simultaneously control bit line voltages and word line voltages of a plurality of memory cell structures to perform the read operation and the program operation on one page (e.g., PG1).

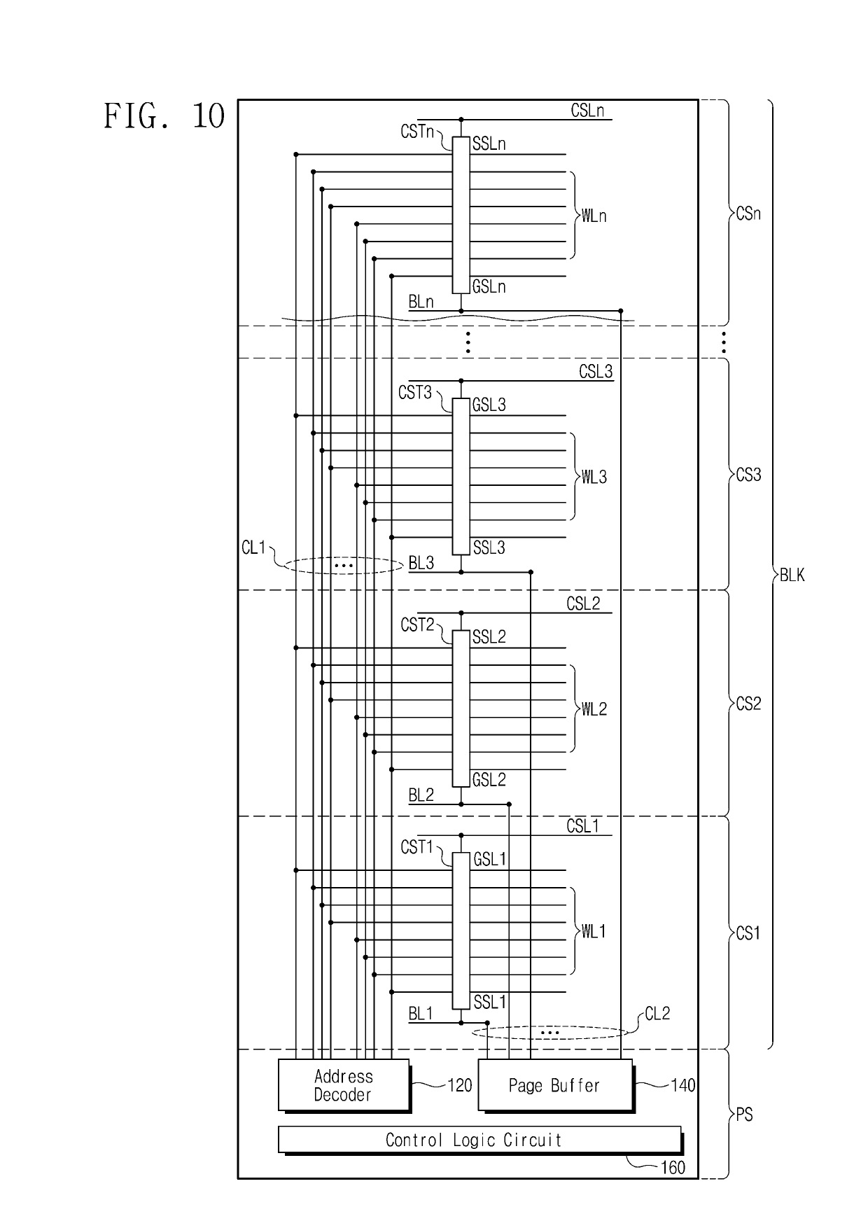

FIG. 10 is another example of a circuit diagram schematically illustrating a nonvolatile memory device of FIG. 1. For brevity of description, the description associated with the same technical characteristics as the embodiments described with reference to FIG. 3 will be omitted, and differences will be described in detail.

Referring to FIG. 10, a nonvolatile memory device may include the peripheral circuit structure PS and the memory block BLK on the peripheral circuit structure PS, and the memory block BLK may include first to n-th memory cell structures CS1 to CSn vertically stacked. A fourth memory cell structure CS4 may be bonded to the third memory cell structure CS3 described with reference to FIG. 3 by using the bonding manner. The n-th memory cell structure CSn may be connected to the (n-1)-th memory cell structure CSn-1 by using the bonding manner.

The n-th memory cell structure CSn may include an n-th bit line BLn, an n-th string selection line SSLn, n-th word lines WLn, an n-th ground selection line GSLn, an n-th common source line CSLn, and an n-th cell string CSTn. In the n-th memory cell structure CSn, the n-th cell string CSTn may be provided in plurality.

Through the first connection lines CL1, the n-th word lines WLn of the n-th memory cell structure CSn may be connected to the first to (n-1)-th word lines WL1 to WLn-1 and may be connected to the address decoder 120.

Through the first connection lines CL1, the n-th string selection line SSLn of the n-th memory cell structure CSn may be connected in common to the first to (n-1)-th string selection lines SSL1 to SSLn-B and may be connected to the address decoder 120. Meanwhile, the first to n-th string selection lines SSL1 to SSLn may be separated from each other so as to be independently controlled.

Through the first connection lines CL1, the n-th ground selection line GSLn of the n-th memory cell structure CSn may be connected in common to the first to (n-1)-th ground selection lines GSL1 to GSLn-1 and may be connected to the address decoder 120. Meanwhile, the first to n-th ground selection lines GSL1 to GSLn may be separated from each other so as to be independently controlled.

The n-th bit lines BLn of the n-th memory cell structure CSn may be connected to the page buffer 140 through the second connection line CL2.

The n-th bit lines BLn of the n-th memory cell structure CSn may be vertically adjacent to the (n-1)-th bit lines BLn-1 of the (n-1)-th memory cell structure CSn-1. Unlike the above description, the n-th common source line CSLn of the n-th memory cell structure CSn may be disposed vertically adjacent to the (n-1)-th bit lines BLn-1 of the (n-1)-th memory cell structure CSn-1.

As described above, according to an embodiment of the present disclosure, “n” memory cell structures may be connected in the bonding manner to constitute the memory block BLK. In this case, “n” sub-pages which are respectively included in the “n” memory cell structures and are connected to the same word line group may constitute one page.

An example in which a bit line (e.g., BL1) of a memory cell structure is placed on a lower portion of the memory cell structure (e.g., CS1) is illustrated in FIG. 10, but the present disclosure is not limited thereto. Locations of a bit line (e.g., BL1) and word lines (e.g., WL1) of each of the memory cell structures CS1 to CS3 may be variously changed.

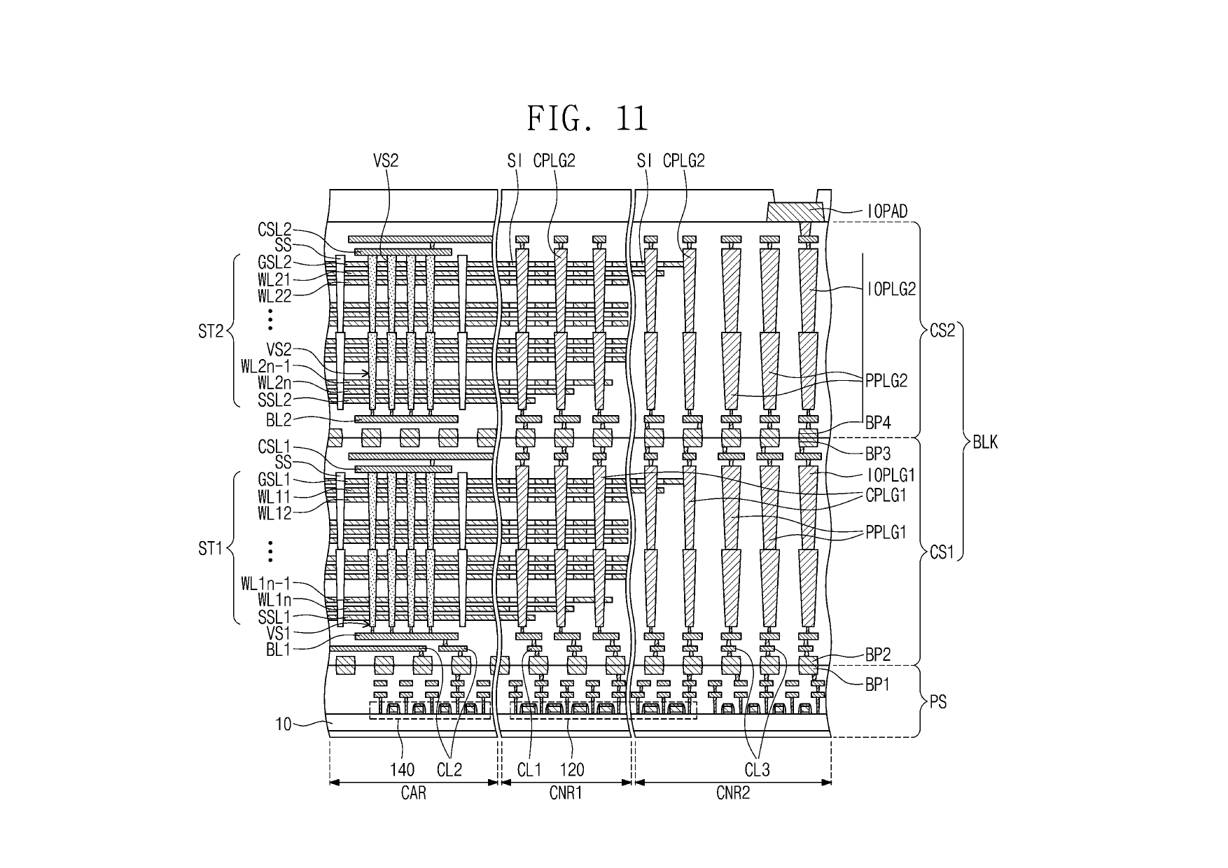

FIG. 11 is a cross-sectional view of a nonvolatile memory device according to an embodiment of the present disclosure. In detail, FIG. 11 shows the case where the memory block BLK includes two memory cell structures CS1 and CS2.

Referring to FIG. 11, a nonvolatile memory device may include a substrate 10, the peripheral circuit structure PS on the substrate 10, and the memory block BLK on the peripheral circuit structure PS. The memory block BLK may include the first memory cell structure CS1 on the peripheral circuit structure PS, and the second memory cell structure CS2 on the first memory cell structure CS1.

The peripheral circuit structure PS may be integrated on the entire surface of the substrate 10 and may include peripheral circuits controlling a memory cell array and first bonding pads BP1 connected to the peripheral circuits.

The peripheral circuits may include the address decoder 120, the voltage generator 130, the page buffer 140, and the control logic circuit 160 described with reference to FIGS. 1 and 2.

The substrate 10 may be, for example, a silicon substrate, a silicon-germanium substrate, a germanium substrate, or a monocrystalline epitaxial layer grown on a monocrystalline silicon substrate. The substrate 10 may include a cell array region CAR, a first connection region CNR1, and a second connection region CNR2.

The page buffer 140 connected to the first and second bit lines BL1 and BL2 may be disposed in the cell array region CAR of the substrate 10. The address decoder 120 connected to the first and second word lines WL11 to WL1n and WL21 to WL2n may be disposed in the first connection region CNR1 of the substrate 10. The voltage generator 130, control logic, etc. may be disposed in the second connection region CNR2 of the substrate 10.

The first bonding pads BP1 may be disposed in the uppermost insulating layer of the peripheral circuit structure PS. The first bonding pads BP1 may be connected to the peripheral circuits through peripheral circuit lines (e.g., conductive lines and conductive plugs). The first bonding pads BP1 may be formed of, for example, copper.

The first memory cell structure CS1 may be provided on the peripheral circuit structure PS. As described with reference to FIG. 4, the first memory cell structure CS1 may include the first cell strings CST11 to CST14 including the first memory cells MC1 arranged in a three-dimensional structure.

In detail, the first memory cell structure CS1 may include the first common source line CSL1, a first stack ST1, first vertical structures VS1, the first bit lines BL1, first cell contact plugs CPLG1, first peripheral contact plugs PPLG1, and first input/output contact plugs IOPLG1. Also, the first memory cell structure CS1 may further include second bonding pads BP2 bonded to the first bonding pads BP1 and third bonding pads BP3 opposite to the second bonding pads BP2.

The first stack ST1 may include first conductive patterns SSL1, WL11 to WL1n, and GSL1 and first interlayer insulating layers alternately stacked along a direction perpendicular to the upper surface of the substrate 10.

The first conductive patterns SSL1, WL11 to WL1n, and GSL1 may include, for example, at least one selected from a doped semiconductor (e.g., doped silicon), metal (e.g., tungsten, molybdenum, nickel, copper, or aluminum), conductive metal nitride (e.g., titanium nitride or tantalum nitride), or transition metal (e.g., titanium or tantalum). The first interlayer insulating layers may include silicon oxide, silicon nitride, silicon oxynitride, and/or a low-k material. For example, the first interlayer insulating layers may include high-density plasma oxide (HDP oxide) or TetraEthylOrthoSilicate (TEOS).

The first stack ST1 may be disposed between separation structures SS extending in parallel along one direction. The separation structures SS may include, for example, an insulating material such as silicon oxide. The first stack ST1 of the first memory cell structure CS1 may be provided in plurality, and the plurality of first stacks ST1 may extend in parallel along one direction.

The first conductive patterns SSL1, WL11 to WL1n, and GSL1 of the first stack ST1 may be stacked to have a stair structure in the first connection region CNR1. That is, as the distance from the peripheral circuit structure PS increases, lengths of the first conductive patterns SSL1, WL11 to WL1n, and GSL1 in one direction may increase. However, the present disclosure is not limited thereto. For example, as the distance from the peripheral circuit structure PS increases, lengths of the first conductive patterns SSL1, WL11 to WL1n, and GSL1 in one direction may decrease.

According to embodiments, the nonvolatile memory device may be a vertical NAND flash device; in this case, the first conductive patterns SSL1, WL11 to WL1n, and GSL1 of the first stack ST1 may be used as first string selection lines (e.g., SSL12a and SSL12b of FIG. 4), first word lines (e.g., WL11 to WL1n of FIG. 4), and ground selection lines (e.g., GSL1 of FIG. 4). The case where a cell string of the first memory cell structure CS1 includes one string selection transistor and one ground selection transistor is illustrated in FIG. 11, but the present disclosure is not limited thereto.

Each of the first conductive patterns SSL1, WL11 to WL1n, and GSL1 may include a pad part in the first connection region CNR1. The pad parts of the first conductive patterns SSL1, WL11 to WL1n, and GSL1 may be placed at locations horizontally and vertically different from each other. The first cell contact plugs CPLG1 may be respectively connected to the pad parts of the first conductive patterns SSL1, WL11 to WL1n, and GSL1.

The plurality of first vertical structures VS1 may vertically penetrate the first stack ST1 in the cell array region CAR. In a plan view, the first vertical structures VS1 may be arranged along one direction or may be arranged in the shape of zigzag. Each of the first vertical structures VS1 may include a vertical channel formed of a semiconductor material. Each of the first vertical structures VS1 may include a lower part penetrating a lower portion of the first stack ST1 and an upper part penetrating an upper portion of the first stack ST1. Each of the lower and upper parts of the first stack ST1 may have a width which gradually increases as the distance from the substrate 10 increases.

In an embodiment, the first bit lines BL1 may be disposed between the first stack ST1 and the peripheral circuit structure PS in a direction (hereinafter referred to as a “vertical direction”) perpendicular to the upper surface of the substrate 10. Each of the first bit lines BL1 may be electrically connected to the first vertical structures VS1 arranged along a direction in which a bit line extends. The first bit lines BL1 may be electrically connected to the second bonding pads BP2 through bit line connection lines CL2 The first bit lines BL1 may include, for example, at least one selected from a doped semiconductor (e.g., doped silicon), metal (e.g., tungsten, molybdenum, nickel, copper, or aluminum), conductive metal nitride (e.g., titanium nitride or tantalum nitride), or transition metal (e.g., titanium or tantalum).

The first common source line CSL1 may be disposed on a first interlayer insulating layer corresponding to the uppermost layer of the first stack ST1. The first common source line CSL1 may directly contact upper surfaces of the first vertical structures VS1. The first common source line CSL1 may be electrically connected to the second bonding pads BP2 through source connection lines. The first common source line CSL1 may include, for example, at least one selected from a doped semiconductor (e.g., doped silicon), metal (e.g., tungsten, molybdenum, nickel, copper, or aluminum), conductive metal nitride (e.g., titanium nitride or tantalum nitride), or transition metal (e.g., titanium or tantalum).

Upper and lower conductive lines may be disposed on and under the first stack ST1. The lower conductive lines disposed under the first stack ST1 may be electrically connected to the second bonding pads BP2, and the upper conductive lines disposed on the first stack ST1 may be electrically connected to the third bonding pads BP3.

In the first connection region CNR1, the first cell contact plugs CPLG1 may be respectively connected to the pad parts of the first conductive patterns SSL1, WL11 to WL1n, and GSL1 through the first stack ST1. The first cell contact plugs CPLG1 may have substantially the same vertical length.

In the first connection region CNR1, the first cell contact plugs CPLG1 may vertically penetrate the pad parts of the first conductive patterns SSL1, WL11 to WL1n, and GSL1, respectively. The first cell contact plugs CPLG1 may be electrically connected to the second bonding pads BP2 through the lower conductive lines. The first cell contact plugs CPLG1 may electrically connect the first conductive patterns SSL1, WL11 to WL1n, and GSL1 and the second bonding pads BP2 through the lower conductive lines. The first cell contact plugs CPLG1 may be electrically connected to the address decoder 120 of the peripheral circuit structure PS.

Sidewalls of the first cell contact plugs CPLG1 may contact the first conductive patterns SSL1, WL11 to WL1n, and GSL1 respectively corresponding thereto. Sidewall insulating patterns SI may be respectively interposed between the first conductive patterns SSL1, WL11 to WL1n, and GSL1 and the first cell contact plugs CPLG1 placed under the pad parts of the first conductive patterns SSL1, WL11 to WL1n, and GSL1. The first cell contact plugs CPLG1 may be some of the first connection lines CL1 described with reference to FIG. 3.

The first peripheral contact plugs PPLG1 and the first input/output contact plugs IOPLG1 may be disposed in an insulating layer so as to be horizontally spaced apart from the first stack ST1 in the second connection region CNR2.

The first peripheral contact plugs PPLG1 may electrically connect the first common source line CSL1 and the second bonding pads BP2 through the lower conductive lines. The first peripheral contact plugs PPLG1 may be electrically connected to the peripheral circuit structure PS. The first peripheral contact plugs PPLG1 may be some of the third connection lines CL3 described with reference to FIG. 3.

Each of the first cell contact plugs CPLG1, the first peripheral contact plugs PPLG1, and the first input/output contact plugs IOPLG1 may include a barrier metal layer including a conductive metal nitride (e.g., titanium nitride or tantalum nitride) and a metal layer including metal (e.g., tungsten, titanium, or tantalum).

First lower conductive lines may be connected to the first cell contact plugs CPLG1 through contact plugs in the first connection region CNR1. Second lower conductive lines may be connected to the first bit lines BL1 through contact plugs in the cell array region CAR. Third lower conductive lines may be connected to the first peripheral contact plugs PPLG1 through contact plugs in the second connection region CNR2.

First upper conductive lines may be connected to the first cell contact plugs CPLG1 through contact plugs in the first connection region CNR1. Second upper conductive lines may be connected to the first bit lines BL1 through contact plugs in the cell array region CAR. Third upper conductive lines may be connected to the first peripheral contact plugs PPLG1 through contact plugs in the second connection region CNR2.

The first, second, and third lower and upper conductive lines may include, for example, at least one selected from metal (e.g., tungsten, copper, or aluminum), conductive metal nitride (e.g., titanium nitride or tantalum nitride), or transition metal (e.g., titanium or tantalum).

The second bonding pads BP2 may be provided in the lowermost insulating layer of the first memory cell structure CS1. The second bonding pads BP2 may be electrically connected to the first bit lines BL1, the first conductive patterns SSL1, WL11 to WL1n, and GSL1, and the first common source line CSL1. A surface of the lowermost insulating layer may directly contact a surface of the uppermost insulating layer of the peripheral circuit structure PS.

The second bonding pads BP2 may be connected to the first bonding pads BP1 electrically and physically by the bonding manner. That is, the second bonding pads BP2 may directly contact the first bonding pads BP1. The second bonding pads BP2 may have substantially the same shape, width, or area as the first bonding pads BP1.

The second bonding pads BP2 may include the same metal material as the first bonding pads BP1. The second bonding pads BP2 may be formed of, for example, copper.

The third bonding pads BP3 may be provided in the uppermost insulating layer of the first memory cell structure CS1 so as to be opposite to the second bonding pads BP2. The third bonding pads BP3 may be electrically connected to the first, second, and third upper conductive lines. The third bonding pads BP3 may be formed of, for example, copper. Continuously, the second memory cell structure CS2 may be disposed on the first memory cell structure CS1. As described with reference to FIG. 3, the second memory cell structure CS2 may include the second cell strings CST2 including the second memory cells MC2 arranged in a three-dimensional structure.

In detail, the second memory cell structure CS2 may include the second common source line CSL2, a second stack ST2, second vertical structures VS2, the second bit lines BL2, second cell contact plugs CPLG2, second peripheral contact plugs PPLG2, and second input/output contact plugs IOPLG2. Also, the second memory cell structure CS2 may further include fourth bonding pads BP4 bonded to the third bonding pads BP3.

The second stack ST2 may include second conductive patterns SSL2, WL21 to WL2n, and GSL2 and second interlayer insulating layers alternately stacked along a direction perpendicular to the upper surface of the substrate 10. The second stack ST2 may include the substantially the same structure and material as the first stack ST1.

The second stack ST2 may be disposed between separation structures SS extending in parallel along one direction. The separation structures SS may include, for example, an insulating material such as silicon oxide. The second stack ST2 of the second memory cell structure CS2 may be provided in plurality, and the plurality of second stacks ST2 may extend in parallel along one direction.

The second conductive patterns SSL2, WL21 to WL2n, and GSL2 of the second stack ST2 may be stacked to have a stair structure in the fisrt connection region CNR1. The second stack ST2 may be disposed in the shape of a vertical mirror symmetry. That is, as the distance from the peripheral circuit structure PS increases, lengths of the second conductive patterns SSL2, WL21 to WL2n, and GSL2 in one direction may increase.

Each of the second conductive patterns SSL2, WL21 to WL2n, and GSL2 may include a pad part in the first connection region CNR1. The pad parts of the second conductive patterns SSL2, WL21 to WL2n, and GSL2 may be placed at locations horizontally and vertically different from each other. The pad parts of the second conductive patterns SSL2, WL21 to WL2n, and GSL2 may vertically overlap the pad parts of the first conductive patterns SSL1, WL11 to WL1n, and GSL1. The second cell contact plugs CPLG2 may be respectively connected to the pad parts of the second conductive patterns SSL2, WL21 to WL2n, and GSL2.

The number of stacked layers of the second conductive patterns SSL2, WL21 to WL2n, and GSL2 of the second stack ST2 may be the same as the number of stacked layers of the first conductive patterns SSL1, WL11 to WL1n, and GSL1 of the first stack ST1. In one direction, the maximum length of the second conductive patterns SSL2, WL21 to WL2n, and GSL2 may be substantially the same as the maximum length of the first conductive patterns SSL1, WL11 to WL1n, and GSL1.

The plurality of second vertical structures VS2 may vertically penetrate the second stack ST2 in the cell array region CAR. The second vertical structures VS2 may include substantially the same structure and material as the first vertical structures VS1.

In a plan view, the second vertical structures VSAND INCORPORATION BY REFERENCE may be arranged along one direction or may be arranged in the shape of zigzag. Each of the second vertical structures VS2 may include a vertical channel formed of a semiconductor material. Each of the second vertical structures VS2 may include a lower part penetrating a lower portion of the second stack ST2 and an upper part penetrating an upper portion of the second stack ST2. Each of the lower and upper parts of the second stack ST2 may have a width which gradually increases as the distance from the substrate 10 increases.

In an embodiment, in a vertical sectional view, the first and second memory cell structures CS1 and CS2 may be bonded to each other such that the first common source line CSL1 of the first memory cell structure CS1 and the second common source line CSL2 of the second memory cell structure CS2 are adjacent to each other. However, the present disclosure is not limited thereto. For example, unlike the example illustrated in FIG. 11, the first and second memory cell structures CS1 and CS2 may be bonded to each other such that the first bit lines BL1 of the first memory cell structure CS1 and the second bit lines BL2 of the second memory cell structure CS2 are adjacent to each other.

In detail, the second common source line CSL2 may be disposed between the second stack ST2 and the fourth bonding pads BP4 in the vertical direction. The second common source line CSL2 may directly contact lower surfaces of the second vertical structures VS2. The second common source line CSL2 may be electrically connected to the fourth bonding pads BP4 through the second peripheral contact plugs PPLG2. The second peripheral contact plugs PPLG2 may be some of the third connection lines CL3 described with reference to FIG. 3.

The second bit lines BL2 may be disposed on a second interlayer insulating layer corresponding to the uppermost layer of the second stack ST2. Each of the second bit lines BL2 may be electrically connected to the second vertical structures VS2 arranged along a direction in which a bit line extends. The second bit lines BL2 may be electrically connected to the fourth bonding pads BP4 through second lower conductive lines.

Second upper and lower conductive lines may be disposed on and under the second stack ST2. The second lower conductive lines disposed under the second stack ST2 may be electrically connected to the fourth bonding pads BP4, and the second upper conductive lines disposed on the second stack ST2 may be electrically connected to the second cell contact plugs CPLG2, the second peripheral contact plugs PPLG2, and the second input/output contact plugs IOPLG2.

In the first connection region CNR1, the second cell contact plugs CPLG2 may be respectively connected to the pad parts of the second conductive patterns SSL2, WL21 to WL2n, and GSL2 through the second stack ST2. The second cell contact plugs CPLG2 may have substantially the same vertical length.

In the first connection region CNR1, the second cell contact plugs CPLG2 may vertically penetrate the pad parts of the second conductive patterns SSL2, WL21 to WL2n, and GSL2, respectively. The second cell contact plugs CPLG2 may electrically connect the second conductive patterns SSL2, WL21 to WL2n, and GSL2 and the fourth bonding pads BP4. The second cell contact plugs CPLG2 may be respectively connected to the first cell contact plugs CPLG1. The second cell contact plugs CPLG2 may vertically overlap the first cell contact plugs CPLG1. Each of the second cell contact plugs CPLG2 may constitute a portion of each of the first connection lines CL1 described with reference to FIG. 3.

That is, the first and second cell contact plugs CPLG1 and CPLG2 may connect the first conductive patterns SSL1, WL11 to WL1n, and GSL1 of the first stack ST1 and the second conductive patterns SSL2, WL21 to WL2n, and GSL2 of the second stack ST2 in a one-to-one correspondence. That is, the first word lines WL11 to WL1n of the first stack ST1 and the second word lines WL21 to WL2n of the second stack ST2 may be respectively connected to each other and may be controlled in common. The first string selection lines SSL1 of the first stack ST1 and the second string selection lines SSL2 of the second stack ST2 may be respectively connected to each other and may be controlled in common. The first ground selection lines GSL1 of the first stack ST1 and the second ground selection lines GSL2 of the second stack ST2 may be respectively connected to each other and may be controlled in common.

Meanwhile, for example, when the memory cell is implemented with the SLC, memory cells connected to word lines controlled in common may constitute one page.

Sidewalls of the second cell contact plugs CPLG2 may contact the second conductive patterns SSL2, WL21 to WL2n, and GSL2 respectively corresponding thereto. Sidewall insulating patterns SI may be respectively interposed between the second conductive patterns SSL2, WL21 to WL2n, and GSL2 and the second cell contact plugs CPLG2 placed under the pad parts of the second conductive patterns SSL2, WL21 to WL2n, and GSL2.

Input/output pads IOPAD may be disposed on the uppermost insulating layer of the second memory cell structure CS2. A passivation layer having an opening exposing some of the input/output pads IOPAD may be disposed on the uppermost insulating layer of the second memory cell structure CS2. The passivation layer may be formed of, for example, a polyimide-based material such as photo sensitive polyimide (PSPI).

Unlike the example illustrated in FIG. 11, as described with reference to FIGS. 3 and 10, according to an embodiment of the present disclosure, the nonvolatile memory device 100 may include three or more memory cell structures CS. In this case, the nonvolatile memory device 100 may further include a plurality of memory cell structures sequentially stacked on the second memory cell structure CS2. Each of the plurality of memory cell structures may be bonded by the bonding manner of the memory cell structures CS1 and CS2 described with reference to FIG. 11.

Meanwhile, FIG. 11 shows an example of a cross-sectional view of a nonvolatile memory device according to an embodiment of the present disclosure, and the present disclosure is not limited thereto. Accordingly, locations of word lines and bit lines of the memory cell structures CS1 and CS2 may be variously changed.

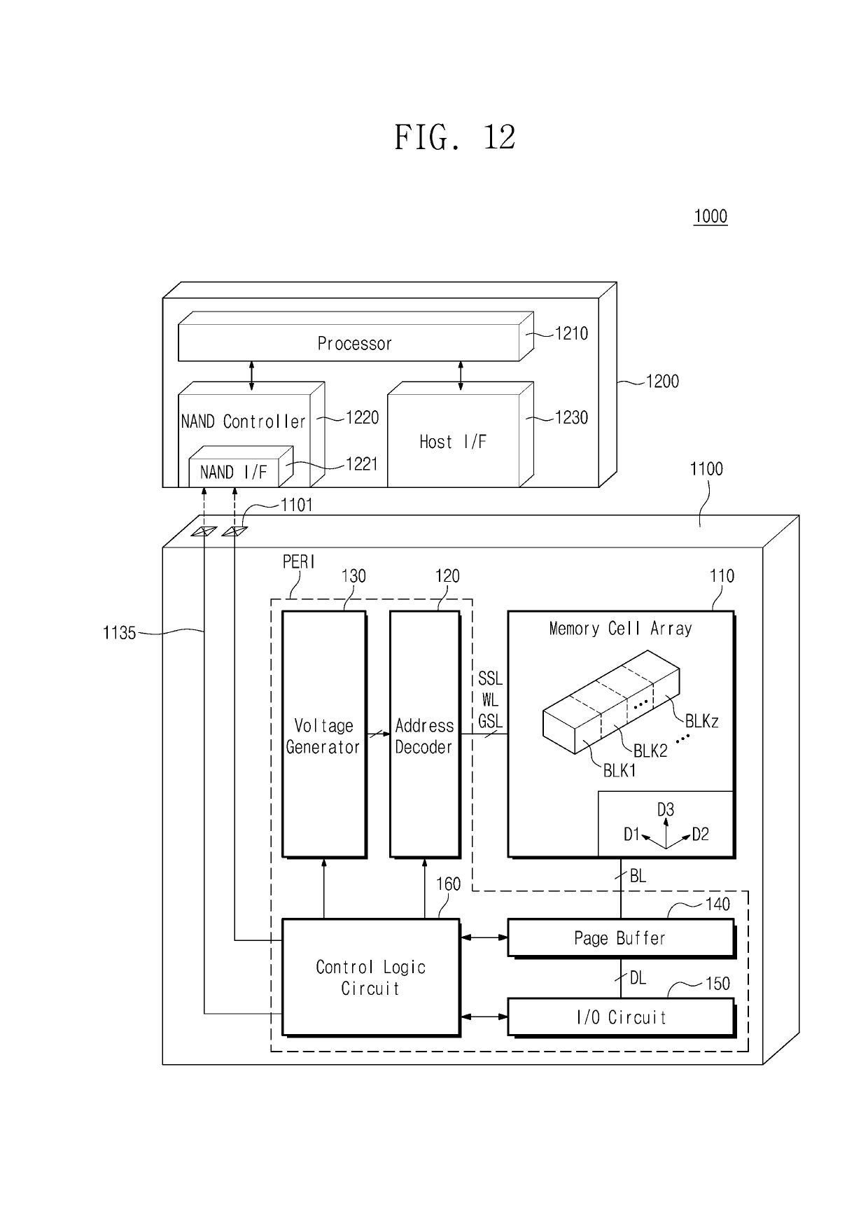

FIG. 12 is a diagram schematically illustrating an electronic system including a semiconductor memory device according to an embodiment of the present disclosure.

Referring to FIG. 12, an electronic system 1000 according to an embodiment of the present disclosure may include a semiconductor device 1100 and a controller 1200 electrically connected to the semiconductor device 1100. The electronic system 1000 may be a storage device that includes one or plural semiconductor devices 1100 or an electronic device that includes the storage device. For example, the electronic system 1000 may be a device, which includes one or plural semiconductor devices 1100, such as a solid state drive (SSD) device, a universal serial bus (USB) device, a computing system, a medical device, or a communication device.

The semiconductor device 1100 may be a nonvolatile memory device, for example, a NAND flash memory device. As described with reference to FIG. 1, the semiconductor device 1100 may include the memory cell array 110 and the peripheral circuits PERI controlling the memory cell array 110. The peripheral circuits PERI may include the address decoder 120, the voltage generator 130, the page buffer 140, the input/output circuit 150, and the control logic circuit 160.

The semiconductor device 1100 may communicate with the controller 1200 through an input/output pad 1101 electrically connected to the control logic circuit 160. The input/output pad 1101 may be electrically connected to the control logic circuit 160 through an input/output connection line 1135.

The controller 1200 may include a processor 1210, a NAND controller 1220, and a host interface 1230. According to embodiments, the electronic system 1000 may include the plurality of semiconductor devices 1100; in this case, the controller 1200 may control the plurality of semiconductor devices 1100.

The processor 1210 may control all operations of the electronic system 1000 including the controller 1200. The processor 1210 may operate based on given firmware and may control the NAND controller 1220 to access the semiconductor device 1100. The NAND controller 1220 may include a NAND interface 1221 that processes the communication with the semiconductor device 1100. A control command for controlling the semiconductor device 1100, data to be recorded at memory cells of the semiconductor device 1100, data read from the memory cells of the semiconductor device 1100, etc. may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

According to the present disclosure, a nonvolatile memory device may include a memory block which is formed by bonding a plurality of memory cell structures respectively formed in separate substrates. Also, one page may be included in the plurality of memory cell structures, and data of one page may be stored in memory cells connected to different word lines. According to the above description, the size of the page may be increased without increasing a length of a word line. Accordingly, a nonvolatile memory device with improved performance and an electronic system including the same may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a first memory cell structure including a plurality of first memory cells connected to a first word line and a plurality of first bit lines; and
a second memory cell structure provided on the first memory cell structure and including a plurality of second memory cells connected to a second word line and a plurality of second bit lines,
wherein the first word line and the second word line are electrically connected,
wherein the plurality of first memory cells are configured to store first sub-page data,
wherein the plurality of second memory cells are configured to store second sub-page data,
wherein the first sub-page data and the second sub-page data are included in first page data, and
wherein the first page data is a minimum program unit of the memory device.

2. The memory device of claim 1, wherein the first memory cell structure includes:
a first cell string including one of the plurality of first memory cells and formed between one of the plurality of first bit lines and a first common source line, and
wherein the second memory cell structure includes:
a second cell string including one of the plurality of second memory cells and formed between one of the plurality of second bit lines and a second common source line.

3. The memory device of claim 2, wherein the first bit lines and the second bit lines are separated from each other.

4. The memory device of claim 1, further comprising:
a third memory cell structure provided on the second memory cell structure and including a plurality of third memory cells connected to a third word line and a plurality of third bit lines,
wherein the third word line is electrically further connected to the first word line and the second word line,
wherein the plurality of third memory cells are configured to store third sub-page data,
wherein the third sub-page data are further included in the first page data.

5. The memory device of claim 4, wherein a size of each of the first sub-page data, the second sub-page data, and the third sub-page data is (16/3) kilobytes or more and is 8 kilobytes or less.

6. The memory device of claim 5, further comprising:
a peripheral circuit structure including an address decoder and a page buffer;
first connection lines connecting the first, second and third word lines with the address decoder; and
second connection lines connecting the first bit lines, the second bit lines, and the third bit lines with the page buffer,
wherein the first memory cell structure is provided on the peripheral circuit structure.

7. The memory device of claim 6, wherein the page buffer includes:
a first page buffer unit connected to the first bit lines;
a second page buffer unit connected to the second bit lines; and
a third page buffer unit connected to the third bit lines.

8. The memory device of claim 7, wherein, in a read operation on the first page data,
the first sub-page data are stored in the first page buffer unit,
the second sub-page data are stored in the second page buffer unit, and
the third sub-page data are stored in the third page buffer unit.

9. The memory device of claim 1, wherein the memory device has a structure in which a first wafer including the first memory cell structure and a second wafer including the second memory cell structure are bonded by a wafer bonding manner.

10. The memory device of claim 1, wherein the first memory cells and the second memory cells are included in a first memory block.

11. A memory device comprising:
a peripheral circuit structure including an address decoder and a page buffer; and
a first memory cell structure to an n-th memory cell structure stacked on the peripheral circuit structure,
wherein the first memory cell structure to the n-th memory cell structure include a plurality of first memory cells to a plurality of n-th memory cells respectively connected to a first word line to an n-th word line,
wherein the first memory cells to the n-th memory cells are connected to a plurality of first bit lines to a plurality of n-th bit lines, respectively,
wherein the plurality of first memory cells to the plurality of n-th memory cells store first sub-page data to n-th sub-page data, respectively,
wherein the first sub-page data to the n-th sub-page data are included in first page data,
wherein the first word line to the n-th word line are electrically connected, and
wherein the first page data is a minimum program unit of the memory device.

12. The memory device of claim 11, wherein the plurality of first bit lines to the plurality of n-th bit lines are separated from each other.

13. The memory device of claim 11, wherein a minimum value of a size of each of the first sub-page data to the n-th sub-page data is (16/n) kilobytes.

14. The memory device of claim 13, wherein a maximum value of a size of each of the first sub-page data to the n-th sub-page data is 8 kilobytes.

15. The memory device of claim 11, further comprising:
connection lines connecting the first word line to the n-th word line with the address decoder.

16. The memory device of claim 15, wherein the page buffer includes a first page buffer unit to an n-th page buffer unit respectively connected to the first memory cell structure to the n-th memory cell structure.

17. The memory device of claim 11, wherein the plurality of first memory cells to the plurality of n-th memory cells are included in a first memory block.

18. An electronic system comprising:
a memory device including a peripheral circuit structure and a memory block on the peripheral circuit structure; and
a controller electrically connected to the memory device through an input/output pad, and configured to control the memory device,
wherein the memory block includes a first memory cell structure to an n-th memory cell structure stacked on the peripheral circuit structure,
wherein the first memory cell structure to the n-th memory cell structure include a plurality of first memory cells to a plurality of n-th memory cells respectively connected to a first word line to an n-th word line,
wherein the first memory cells to the n-th memory cells are connected to a plurality of first bit lines to a plurality of n-th bit lines, respectively,
wherein the plurality of first memory cells to the plurality of n-th memory cells store first sub-page data to n-th sub-page data, respectively,
wherein the first sub-page data to the n-th sub-page data are included in first page data,
wherein the first word line to the n-th word line are electrically connected, and
wherein the first page data is a minimum program unit of the memory device.

19. The electronic system of claim 18, wherein the first to n-th sub-page data have the same size, and
wherein a minimum value of a size of each of the first to n-th sub-page data is (16/n) kilobytes.

20. The electronic system of claim 18, wherein the peripheral circuit structure includes a page buffer, and
wherein the page buffer includes a first page buffer unit to an n-th page buffer unit respectively connected to the first memory cell structure to the n-th memory cell structure.
